(19) United States
(12) Patent Application Publication
(10) Pub. No.: US 2016/0064312 A1
(43) Pub. Date: Mar. 3, 2016

(54) MANUFACTURING METHOD OF SEMICONDUCTOR DEVICE

(71) Applicant: Renesas Electronics Corporation, Tokyo (JP)

(72) Inventor: Koji Bando, Tokyo (JP)

(73) Assignee: RENESAS ELECTRONICS CORPORATION

(21) Appl. No.: 14/827,973

(22) Filed: Aug. 17, 2015

(30) Foreign Application Priority Data
Aug. 26, 2014 (JP) 2014-171597

(51) Int. Cl. H01L 23/495; H01L 21/52; H01L 25/07

(52) U.S. Cl. CPC H01L 23/49575; H01L 25/072; H01L 21/52; H01L 2021/60277

(57) ABSTRACT

Provided is a method for manufacturing a semiconductor device that can achieve downsizing of the semiconductor device. Convex portions are pressed against side surfaces other than one side surface of one chip mounting portion, thereby fixing the chip mounting portion without forming a convex portion corresponding to the one side surface of the chip mounting portion. Likewise, convex portions are pressed against side surfaces other than one side surface of the other chip mounting portion, thereby fixing the other chip mounting portion without forming a convex portion corresponding to the one side surface of the other chip mounting portion.

### CROSS-REFERENCE TO RELATED APPLICATIONS

The disclosure of Japanese Patent Application No. 2014-171597 filed on Aug. 26, 2014 including the specification, drawings and abstract is incorporated herein by reference in its entirety.

### BACKGROUND

The present invention relates to techniques for manufacturing semiconductor devices, and more specifically, to a technique that can be effectively applied to manufacturing a semiconductor device that serves as, for example, a component of an inverter.

Japanese Unexamined Patent Application Publication No. 2003-197664 (Patent Document 1) describes a technique that involves removing a semiconductor device with a heat dissipation portion from a die by creating a concave portion in the heat dissipation portion and inserting a pin into the concave portion.

Japanese Unexamined Patent Application Publication No. 2008-283138 (Patent Document 2) describes a technique for fixing a heatsink by a molding die with a projection.

Japanese Unexamined Patent Application Publication No. Hei 8(1996)-172145 (Patent Document 3) describes a technique that involves forming a cutout portion for positioning in the corner (edge) of a heatsink, and pressing a fixing portion to the cutout portion, thereby positioning the heatsink.

### RELATED ART DOCUMENTS

### Patent Documents

[Patent Document 1]

Japanese Unexamined Patent Application Publication No. 2003-197664

[Patent Document 2]

Japanese Unexamined Patent Application Publication No. 2008-283138

[Patent Document 3]

Japanese Unexamined Patent Application Publication No. Hei 8(1996)-172145

### SUMMARY

Motors are mounted, for example, in electric vehicles, hybrid vehicles, etc. One example of a motor is a permanent magnet synchronous motor (hereinafter referred to as a “PM motor”). The PM motor is generally used as a motor for driving electric vehicles, hybrid vehicles, and the like. On the other hand, the need for switched reluctance motors (hereinafter referred to as an “SR motor”) has recently increased in view of reduction in cost.

To control the SR motor, an inverter circuit dedicated to the SR motor is needed. The inverter circuit for the SR motor is put into commercial production in the form of a power module (electronic device). Most components of the power module that are designed for the inverter circuit dedicated to the SR motor are bare chip mounting products, and thus need to be improved in terms of higher performance and downsizing of the power module.

For this reason, the inventors have studied the use of semiconductor devices (packaged products) as the component for the power module corresponding to the inverter circuit for the SR motor in order to enhance the performance and reduce the size of the power module. These studies found that each package produced requires two chip mounting portions that are electrically isolated from each other in terms of the characteristics of the inverter circuit dedicated to the SR motor.

Thus, particularly, to reduce the size of the packaged product, these two chip mounting portions need to be as close to each other as possible while remaining electrically isolated mutually. This leads to the need for a technique that can accurately position and arrange two chip mounting portions close to each other in a manufacturing procedure of the packaged product. Specifically, a positioning jig that can position two chip mounting portions as close to each other as possible needs to be developed.

Other problems and new features of the present invention will be clearly understood by the following detailed description of the present specification in connection with the accompanying drawings.

According to one embodiment of the invention, a method for manufacturing a semiconductor device includes the step of arranging a first chip mounting portion and a second chip mounting portion over a main surface of a jig such that one side surface of the first chip mounting portion faces one side surface of the second chip mounting portion. Then, first convex portions of the jig are pressed against respective side surfaces other than the one side surface of the first chip mounting portion, thereby positioning the first chip mounting portion over the main surface of the jig, and second convex portions of the jig are pressed against respective side surfaces other than the one side surface of the second chip mounting portion, thereby positioning the second chip mounting portion over the main surface of the jig.

Accordingly, the one embodiment of the present invention can downsize the semiconductor device.

### BRIEF DESCRIPTION OF THE DRAWINGS

FIGS. 1A to 1C are diagrams for explaining the rotation principle of the SR motor.

FIG. 2 is a circuit diagram showing an inverter circuit arranged between a DC power source and the SR motor;

FIG. 3 is a diagram for explaining the operation of the inverter circuit in a first embodiment of the invention;

FIG. 4A is a diagram showing a part of an inverter circuit for a PM motor, and FIG. 4B is a diagram showing a part of the inverter circuit for the SR motor;

FIG. 5 is a plan view showing an outer appearance of a semiconductor chip with an IGBT formed therein;

FIG. 6 is a plan view showing a back surface opposite to a front surface of the semiconductor chip;

FIG. 7 is a circuit diagram showing one example of a circuit formed on the semiconductor chip;

FIG. 8 is a cross-sectional view showing a device structure of the IGBT in the first embodiment;

FIG. 9 is a plan view showing an outer appearance of a semiconductor chip with a diode formed thereat;

FIG. 10 is a cross-sectional view showing a device structure of the diode;

FIG. 11A is a plan view of the semiconductor device as viewed from the front surface side thereof in the first embodiment, FIG. 11B is a side view of the semiconductor device as viewed from a side surface thereof in the first embodiment, and FIG. 11C is a plan view of the semiconductor device as viewed from the back surface side thereof in the first embodiment.

FIG. 12A is a plan view of an internal structure of the semiconductor device in the first embodiment, FIG. 12B is a cross-sectional view taken along the line A-A of FIG. 12A, and FIG. 12C is a cross-sectional view taken along the line B-B of FIG. 12A.

FIG. 13 is an enlarged view of a partial region of FIG. 12B.

FIG. 14 is a diagram for explaining “a structure with a stepped portion at its side surface”.

FIG. 15 is another diagram for explaining “a structure with a stepped portion at its side surface”.

FIG. 16A is a perspective view of a manufacturing step of the semiconductor device in the first embodiment, and FIG. 16B is a cross-sectional view taken along the line A-A of FIG. 16A.

FIG. 17A is a perspective view of another manufacturing step of the semiconductor device in the first embodiment, and FIG. 17B is a cross-sectional view taken along the line A-A of FIG. 17A.

FIG. 18 is an exemplary diagram showing a step of forming a conductive paste over two chip mounting portions.

FIG. 19A is a perspective view of another manufacturing step of the semiconductor device in the first embodiment, and FIG. 19B is a cross-sectional view taken along the line A-A of FIG. 19A.

FIG. 20A is a perspective view of another manufacturing step of the semiconductor device in the first embodiment, and FIG. 20B is a cross-sectional view taken along the line B-B of FIG. 20A.

FIG. 21A is a perspective view of another manufacturing step of the semiconductor device in the first embodiment, and FIG. 21B is a cross-sectional view taken along the line B-B of FIG. 21A.

FIG. 22A is another perspective view of another manufacturing step of the semiconductor device in the first embodiment, and FIG. 22B is another cross-sectional view taken along the line B-B of FIG. 22A.

FIG. 23 is a perspective view showing another manufacturing step of the semiconductor device in the first embodiment.

FIG. 24A is another perspective view of another manufacturing step of the semiconductor device in the first embodiment, and FIG. 24B is a cross-sectional view taken along the line B-B of FIG. 24A.

FIG. 25A is a plan view showing a state in which two chip mounting portions are arranged on a lower jig in the first embodiment, FIG. 25B is a cross-sectional view taken along the line A-A of FIG. 25A, and FIG. 25C is a cross-sectional view taken along the line B-B of FIG. 25A.

FIG. 26A is a plan view showing a state in which an upper jig is arranged on the lower jig in the first embodiment, FIG. 26B is a cross-sectional view taken along the line A-A of FIG. 26A, and FIG. 26C is a cross-sectional view taken along the line B-B of FIG. 26A.

FIG. 27A is a plan view showing a state in which a lead frame is arranged on the upper jig in the first embodiment, FIG. 27B is a cross-sectional view taken along the line A-A of FIG. 27A, and FIG. 27C is a cross-sectional view taken along the line B-B of FIG. 27A.

FIG. 28 is a schematic diagram showing a state in which the two chip mounting portions are fixed by the lower jig.

FIG. 29 is a diagram for explaining a first related art.

FIG. 30 is a diagram for explaining a second related art.

FIG. 31 is a schematic diagram showing a state in which one chip mounting portion is fixed by a lower jig.

FIG. 32 is a diagram for explaining an advantage obtained by a second aspect of the first embodiment.

FIG. 33 is a schematic diagram showing a state in which two chip mounting portions are fixed by a lower jig in a first modified example.

FIG. 34 is a schematic diagram showing a state in which two chip mounting portions are fixed by a lower jig in a second modified example.

FIG. 35 is a schematic diagram showing a state in which two chip mounting portions are fixed by a lower jig in a third modified example.

FIG. 36 is a schematic diagram showing a state in which two chip mounting portions are fixed by a lower jig in a fourth modified example.

FIG. 37 is a schematic diagram showing a state in which two chip mounting portions are fixed by a lower jig according to a second embodiment of the invention.

FIG. 38 is a schematic diagram showing a state in which one chip mounting portion is fixed by the lower jig.

FIG. 39 is a schematic diagram showing the structure excluded from the concept of the second embodiment.

### DETAILED DESCRIPTION

The following preferred embodiments of the invention may be described below by being divided into a plurality of sections or embodiments for convenience, if necessary, which are not independent from each other unless otherwise specified. One of the sections or embodiments may be a modified example, a detailed description, supplementary explanation, and the like of a part or all of the other.

Even when referring to a specific number about an element and the like (including the number of elements, a numerical value, an amount, a range, and the like) in the following embodiments, the invention is not limited to the specific number, and may take the number greater than, or less than the specific numeral number, unless otherwise specified, and except when clearly limited to the specific number in principle.

It is obvious that the components (including elemental steps etc.) in the embodiments below are not necessarily essential unless otherwise specified, and except when clearly considered to be essential in principle.

Likewise, when referring to the shape of one component, or the positional relationship between the components in the following embodiments, any shape or positional relationship substantially similar or approximate to that described herein may be included in the invention unless otherwise specified and except when clearly considered not to be so in principle. The same goes for the above number, and the range.

In all drawings for explaining the embodiments, the same parts are indicated by the same or similar reference characters in principle, and the repeated description thereof will be omitted. Even some plan views may be designated by hatching for easy understanding.

### First Embodiment

A first embodiment of the invention relates to a technical idea regarding a power module including an inverter circuit for controlling an SR motor. Here, in the description of the present specification, conceptually, the entire power module corresponds to an electronic device, while an electronic part including a semiconductor chip among components of the power module corresponds to a semiconductor device.

### <Rotation Principle of SR Motor>

Motors are mounted, for example, in electric automobiles, hybrid automobiles etc. Suitable motors include a PM motor, and a SR motor. The SR motor has advantages of low cost and high-speed rotation, as compared to the PM motor. Specifically, the SR motor has the advantage that it can achieve the low cost compared to the PM motor as no rare earth (rare metal) is used and the structure of a rotor (rotator) has a simple structure. Further, the SR motor has another advantage that it enables high-speed rotation of the rotor as the rotor has a simple, tough structure made of an iron ingot. Thus, the need for the SR motor has increased in recent years in terms of low cost. For this reason, the first embodiment of the invention focuses on the SR motor. In the following, first, the rotation principle of the SR motor will be described.

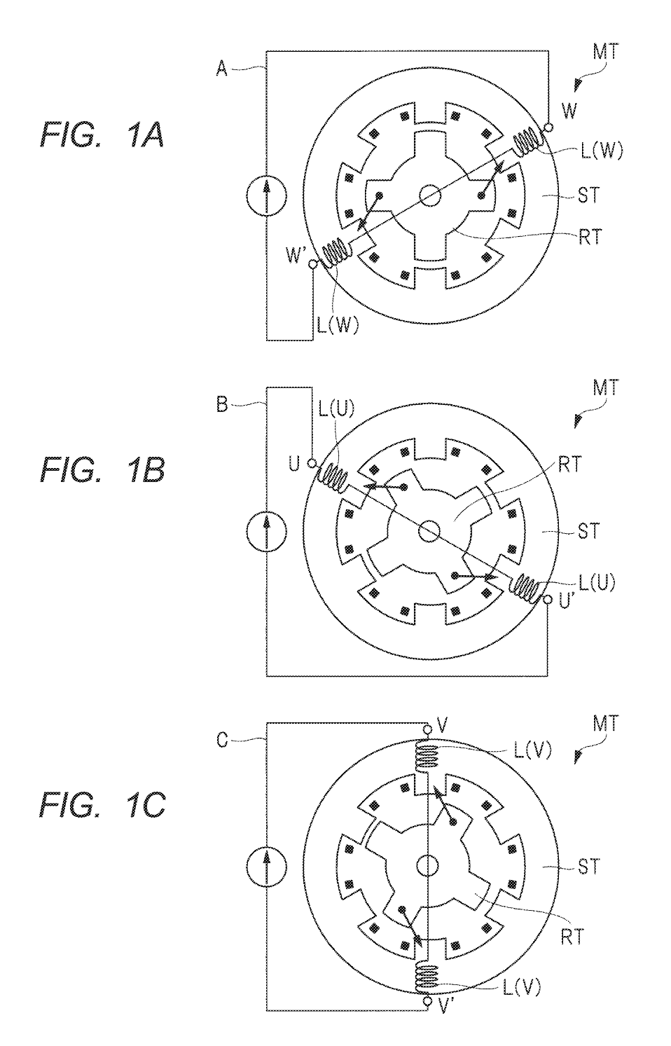

FIGS. 1A to 1C are diagrams for explaining the rotation principle of the SR motor MT. As shown in FIG. 1A, the SR motor MT includes a stator ST and a rotor RT. In the stator ST, the rotor RT is rotatably arranged. Coils L(W) are formed by winding a wire between terminals W and W′ of the stator ST (between terminals W-W′). Once current passes through a closed circuit A including the coils L(W) wound between the terminals W and W′ of the stator ST, an electromagnet is formed due to the current flowing through the coils L(W) wound between the terminals W and W′. As a result, for example, the rotor RT made of iron receives attraction which is a magnetic force generated by the electromagnet, and is attracted in the direction indicated by an arrow of FIG. 1A.

Subsequently, when the closed circuit A including the coils L(W) wound between the terminals W-W′ of the stator ST is released, and the flow of current is interrupted, the magnetic force generated by the electromagnet due to the current through the coils L(W) wound between the terminals W-W′ is lost. Thus, the attraction applied to the rotor RT by the electromagnet due to the current through the coils L(W) wound between the terminals W-W′ is eliminated. Thereafter, as shown in FIG. 1B, once current passes through a closed circuit B including the coils L(U) wound between terminals U and U′ (between terminals U-U′) of the stator ST, an electromagnet is formed due to the current flowing through the coils L(U) wound between the terminals U and U′. As a result, the rotor RT receives attraction from the electromagnet and is attracted in the direction indicated by an arrow of FIG. 1B.

Then, when the closed circuit B including the coils L(U) wound between the terminals U-U′ of the stator ST is released, and the flow of current is interrupted, the magnetic force generated by the electromagnet due to the current through the coils L(U) wound between the terminals U-U′ is lost. Thus, the attraction applied to the rotor RT by the electromagnet due to the current through the coils L(U) wound between the terminals U-U′ is eliminated. Thereafter, as shown in FIG. 1C, once current passes through a closed circuit C including the coils L(V) wound between terminals V and V′ (between terminals V-V′) of the stator ST, an electromagnet is formed due to the current flowing through the coils L(V) wound between the terminals V and V′. As a result, the rotor RT receives attraction from the electromagnet and is attracted in the direction indicated by an arrow of FIG. 1C.

In the way described above, switching is performed among the closed circuits A, B, and C, thereby allowing the current to pass through the corresponding closed circuit in turn, producing an electromagnet. The attraction from the electromagnet permits the rotor RT to continuously rotate counterclockwise, for example, as shown in FIGS. 1A to 1C. This is the principle of rotation of the SR motor MT. It is found out that to rotate the SR motor MT, it is necessary to allow current to flow by switching among the closed circuits A, B, and C. A circuit for controlling the switch among the closed circuits A, B, and C is an inverter circuit. That is, the inverter circuit is configured to control the current flowing through the corresponding closed circuit by sequentially switching among the closed circuits A, B, and C. Now, the structure of the inverter circuit with such a function will be described.

### <Structure of Inverter Circuit>

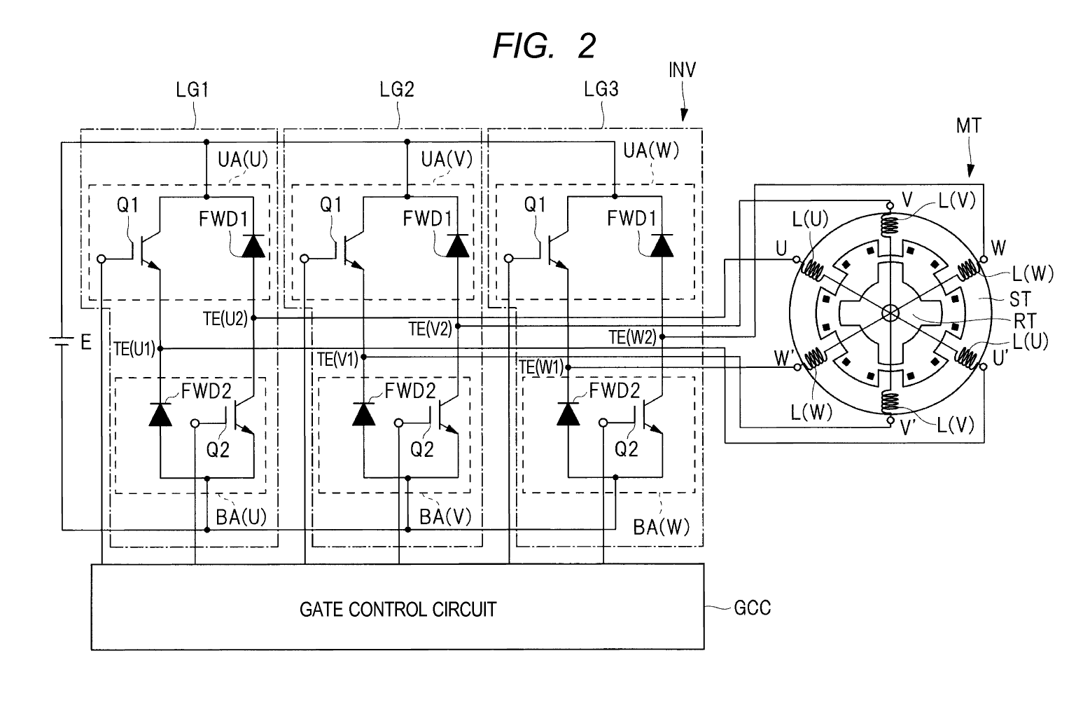

FIG. 2 is a circuit diagram showing an inverter circuit INV arranged between a DC power source E and an SR motor MT. As shown in FIG. 2, the inverter circuit INV includes a first leg LG1, a second leg LG2, and a third leg LG3, which are coupled in parallel with the DC power source E. The first leg LG1 is comprised of an upper arm UA(U) and a lower arm BA(U) which are coupled in series. The second leg LG2 is comprised of an upper arm UA(V) and a lower arm BA(V) which are coupled in series. The third leg LG3 is comprised of an upper arm UA (W) and a lower arm BA (W) which are coupled in series. The upper arm UA(U) is comprised of an IGBTQ1, and a diode FWD1, and the lower arm BA(U) is comprised of an IGBTQ2, and a diode FWD2. At this time, both the IGBTQ1 of the upper arm UA(U) and the diode FWD2 of the lower arm BA(U) are coupled to a terminal TE(U1), so that the IGBTQ1 and the diode FWD2 are coupled in series. On the other hand, both the diode FWD1 of the upper arm UA(U) and the IGBTQ2 of the lower arm BA(U) are coupled to a terminal TE(U2), so that the diode FWD1 and the IGBTQ2 are coupled in series. The terminal TE(U1) is coupled to a terminal U′ of the SR motor, and the terminal TE(U2) is coupled to a terminal U of the SR motor. That is, the coils L(U) existing between the terminals U and U′ of the SR motor MT are coupled to between the terminal TE(U1) and the terminal TE(U2) of the inverter circuit INV.

Likewise, the upper arm UA(V) is comprised of an IGBTQ1 and a diode FWD1, and the lower arm BA(V) is comprised of an IGBTQ2 and a diode FWD2. At this time, both the IGBTQ1 of the upper arm UA(V) and the diode FWD2 of the lower arm BA(V) are coupled to a terminal TE(V1), so that the IGBTQ1 and the diode FWD2 are coupled in series. On the other hand, both the diode FWD1 of the upper arm UA(V) and the IGBTQ2 of the lower arm BA(V) are coupled to a terminal TE(V2), so that the diode FWD1 and the IGBTQ2 are coupled in series. The terminal TE(V1) is coupled to a terminal V′ of the SR motor, and the terminal TE(V2) is coupled to a terminal V of the SR motor. That is, the coils L(V) existing between the terminals V and V′ of the SR motor MT are coupled to between the terminal TE(V1) and the terminal TE(V2) of the inverter circuit INV.

Likewise, the upper arm UA(W) is comprised of an IGBTQ1 and a diode FWD1, and the lower arm BA(W) is comprised of an IGBTQ2 and a diode FWD2. At this time, both the IGBTQ1 of the upper arm UA(W) and the diode FWD2 of the lower arm BA(W) are coupled to a terminal TE(W1), so that the IGBTQ1 and the diode FWD2 are coupled in series. On the other hand, both the diode FWD1 of the upper arm UA (W) and the IGBTQ2 of the lower arm BA (W) are coupled to a terminal TE(W2), so that the diode FWD1 and the IGBTQ2 are coupled in series. The terminal TE(W1) is coupled to a terminal W′ of the SR motor, and the terminal TE(W2) is coupled to a terminal W of the SR motor. That is, the coils L(W) existing between the terminals W and W′ of the SR motor MT are coupled to between the terminal TE(W1) and the terminal TE(W2) of the inverter circuit INV.

A gate electrode of the IGBTQ1, which is a component of each of the upper arms UA(U), UA(V), and UA (W), is electrically coupled to agate control circuit GCC. An on/off operation (switching operation) of the IGBTQ1 in each of the upper arms UA(U), UA(V), and UA (W) is controlled by a gate control signal from the gate control circuit GCC. Likewise, a gate electrode of the IGBTQ2, which is a component of each of the lower arms BA(U), BA(V), and BA (W), is electrically coupled to the gate control circuit GCC. An on/off operation of the IGBTQ2 in each of the lower arms BA(U), BA(V), and BA (W) is controlled by a gate control signal from the gate control circuit GCC.

Here, for example, a metal oxide semiconductor field effect transistor (power MOSFET) is considered to be used as a switching element for the inverter circuit INV. The power MOSFET is of the voltage driven type that controls the on/off operation of the inverter circuit by a voltage applied to the gate electrode, and thus has an advantage of enabling high-speed switching. On the other hand, the power MOSFET tends to increase on-resistance with increasing breakdown voltage, producing a large amount of heat. This is because the power MOSFET ensures the appropriate breakdown voltage by increasing the thickness of a low-concentration epitaxial layer (drift layer), but increases its resistance as a side effect with increasing thickness of the low-concentration epitaxial layer.

In contrast, a bipolar transistor is proposed that can handle a large electric power as a switching element. The bipolar transistor is of a current-driven type that controls the on/off operation by a base current, and thus generally has a low switching speed as compared to the power MOSFET described above.

As mentioned above, the power MOSFET and the bipolar transistor cannot be readily used in applications to devices that need a large electric power and high-speed switching, such as motors of electric automobiles, or hybrid automobiles. For this reason, the IGBT is used in those applications that requires a large electric power and high-speed switching as described above. The IGBT is comprised of a combination of a power MOSFET and a bipolar transistor. The IGBT is a semiconductor element having the high-speed switching characteristics of the power MOSFET, as well as the high breakdown voltage characteristics of the bipolar transistor. In this way, the IGBT can achieve both the large electric power and the high-speed switching. This means that the IGBT is the semiconductor element appropriate for applications requiring the large current and high-speed switching. As mentioned above, the inverter circuit INV of the first embodiment employs the IGBT as a switching element.

The inverter circuit INV of the first embodiment includes the first to third legs LG1 to LG3 which are coupled in parallel with each other. Each of the first to third legs LG1 to LG3 includes two IGBTs (IGBTQ1 and IGBTQ2), and two diodes (diode FWD1 and diode FWD2). This means that the inverter circuit INV of the first embodiment includes the six IGBTs and the six diodes. In the thus-configured inverter circuit INV, the three IGBTQ1 and the three IGBTQ2 are controlled to be turned on/off (which is a switching operation) by the gate control circuit GCC, thus enabling rotation of the SR motor MT. A description will be given of the operation of the inverter circuit INV for rotating the SR motor MT with reference to the accompanying drawings.

### <Operation of Inverter Circuit>

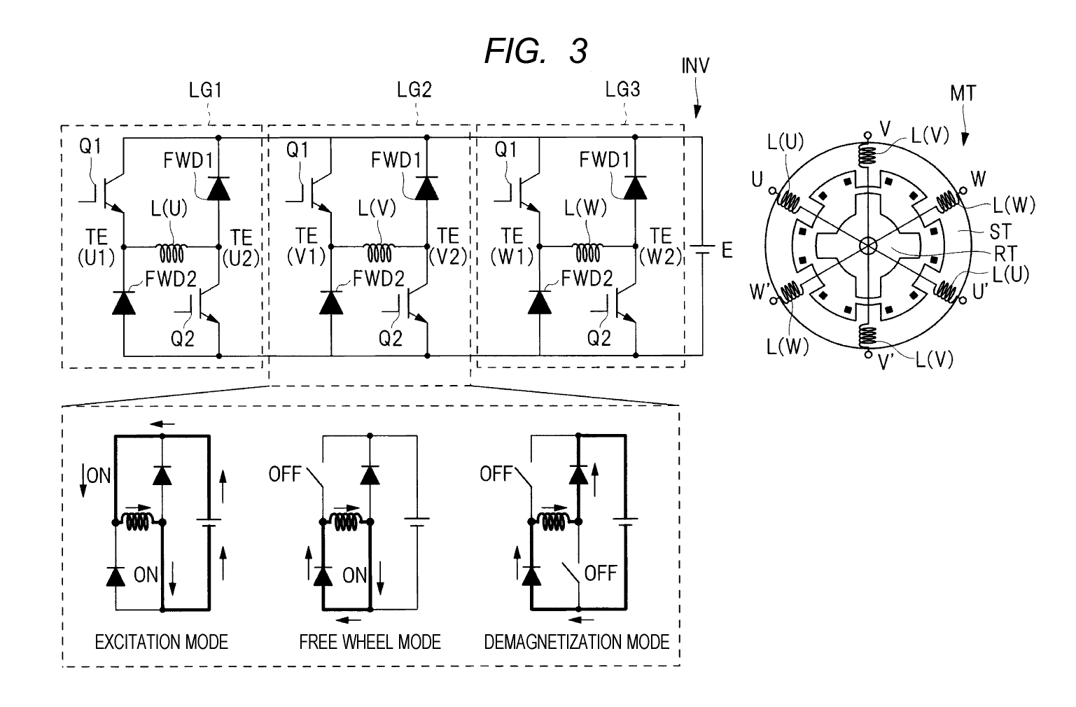

FIG. 3 is a diagram for explaining the operation of the inverter circuit INV in the first embodiment. The inverter circuit INV shown in FIG. 3 is a circuit for rotatably driving the SR motor MT, and includes the first to third legs LG1 to LG3. At this time, for example, the first leg LG1 is a circuit for controlling current passing through the coils L(U) provided between the terminals U and U′ (between the terminals U-U′) of the SR motor MT, while the second leg LG2 is a circuit for controlling current passing through the coils L(V) provided between the terminals V and V′ (between the terminals V-V′) of the SR motor MT. Likewise, the third leg LG3 is a circuit for controlling current passing through the coils L(W) provided between the terminals W and W′ (between the terminals W-W′) of the SR motor MT. That is, the inverter circuit INV shown in FIG. 3 controls the current passing through the coils L(U) by use of the first leg LG1, the current passing through the coils L(V) by use of the second leg LG2, and the current passing through the coils L(W) by use of the third leg LG3. In the inverter circuit INV shown in FIG. 3, the control of current to the coils L(U) by the first leg LG1, the control of current to the coils L(V) by the second leg LG2, and the control current to the coils L(W) by the third leg LG3 are performed in the same way at different timings. Now, the control of current to the coils L(V) by the second leg LG2 will be described by way of example.

Referring to FIG. 3, first, when current starts to pass through the coils L(V) of the SR motor MT, as shown in an excitation mode, the IGBTQ1 is turned on and the IGBTQ2 is also turned on. At this time, the current is supplied from the DC power source E through the IGBTQ1, which is turned on, and then from the terminal TE(V1) into the coils L(V). The current returns to the DC power source E through the IGBTQ2, which is turned on, from the coils L(V) via the terminal TE(V2). In this way, the current can pass through the coils L(V). As a result, an electromagnet is formed between the V-V′ of the stator ST of the SR motor MT, and the attraction generated by the electromagnet is applied to the rotor RT. Thereafter, to maintain the attraction by the electromagnet, the current passing through the coil L(V) of the SR motor MT is maintained. Specifically, as shown in a free wheel mode of FIG. 3, the IGBTQ1 is turned off, and the IGBQ2 is kept on. In this case, as shown in the free wheel mode of FIG. 3, the coil L(V), the IGBTQ2 turned on, and the diode FWD2 form the closed circuit, through which the current continues to pass. As a result, the current passing through the coils L(V) is maintained, so that the attraction from the electromagnet due to the coil L(V) continues to be applied to the rotor RT. Subsequently, the current through the coil L(V) is eliminated. Specifically, as shown in a demagnetization mode of FIG. 3, the IGBTQ1 is turned off, and the IGBQ2 is also turned off. In this case, as indicated by the demagnetization mode of FIG. 3, a residual power in the coil L(V) of the closed circuit comprised of the coils L(V), the IGBTQ2 turned on, and the diode FWD2 is eliminated via the diode FWD1 by turning off the IGBTQ2. As a result, the current passing through the coil L(V) is decreased and stopped, eliminating the electromagnet generated by the current passing through the coil L(V). Thus, the attraction applied to the rotor RT by the electromagnet due to the current through the coils L(V) is eliminated. Such an operation is repeatedly performed at different timings by switching among the first to third legs LG1 to LG3, whereby the rotor RT of the SR motor MT can be rotated. In the way described above, it is found that the control of current through the inverter circuit INV in the first embodiment can rotate the SR motor MT.

<Difference from Inverter Circuit for PM Motor>

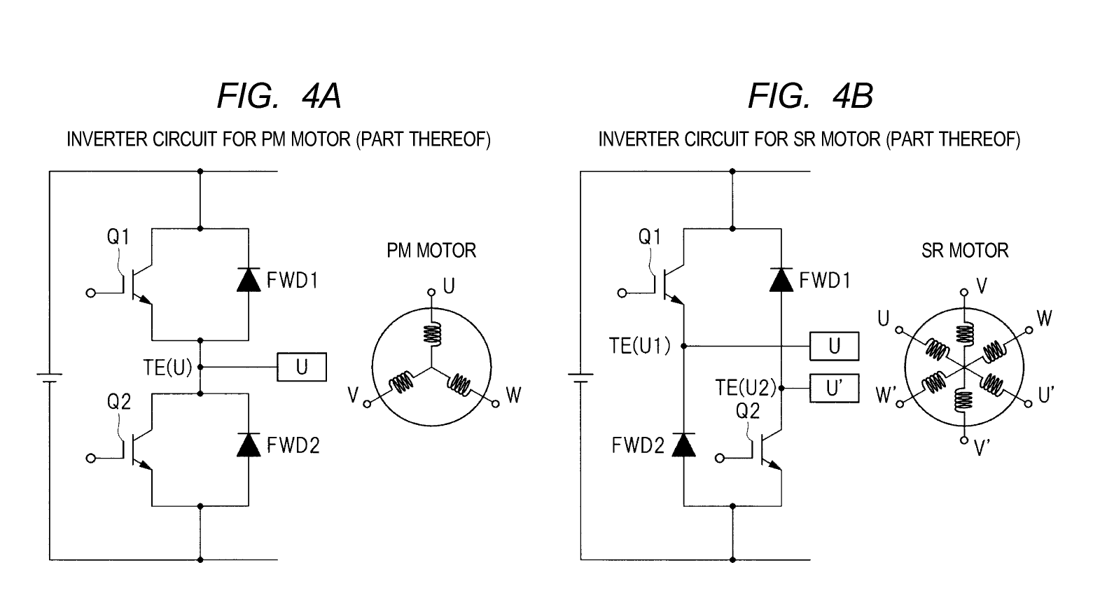

Next, a description will be given of differences of the inverter circuit for the SR motor in the first embodiment from the inverter circuit for the PM motor generally used. FIGS. 4A and 4B are diagrams for explaining differences between the inverter circuit for the PM motor and the inverter circuit for the SR motor. Specifically, FIG. 4A is a diagram showing a part of an inverter circuit for a PM motor, and FIG. 4B is a diagram showing a part of the inverter circuit for the SR motor.

FIG. 4A illustrates a part of the inverter circuit that is electrically coupled to the terminal U(U phase) of the PM motor. Specifically, the IGBTQ1 and the diode FWD1 that configure the upper arm are coupled in antiparallel, while the IGBTQ2 and the diode FWD2 that configure the lower arm are coupled in antiparallel. One terminal TE(U) is provided between the upper arm and the lower arm, and coupled to the terminal U of the PM motor. In the inverter circuit for the PM motor thus configured, as shown in FIG. 4A, a U phase coil, a V phase coil, and a W phase coil of the PM motor are coupled together with three-phase wiring connection (e.g., star connection). Upper and lower arm elements for driving the respective coils are controlled not to operate simultaneously. Thus, the inverter circuit for the PM motor is controlled such that the coils of two phases are driven in pairs as follows: for example, U phase coil+V phase coil; V phase coil+W phase coil; and W phase coil+U phase coil, in this order. In the inverter circuit for the PM motor, once the IGBT is turned off for phase conversion after current passes through the coil by turning on IGBT, a regeneration current generated by the residual power is permitted to pass through the diode in the arm, which eliminates the residual power. Therefore, the inverter circuit for the PM motor needs to have the IGBT and the diode arranged in pairs. As a result, in the inverter circuit for the PM motor, as shown in FIG. 4A, one terminal TE(U) is provided between the upper arm and the lower arm.

FIG. 4B illustrates a part of the inverter circuit that is electrically coupled to the terminals U and U′ of the SR motor. Specifically, the IGBTQ1 included in the upper arm and the diode FWD2 included in the lower arm are coupled in series, and the terminal TE(U1) is provided between the IGBTQ1 included in the upper arm and the diode FWD2 included in the lower arm. Specifically, the diode FWD1 included in the upper arm and the IGBTQ2 included in the lower arm are coupled in series, and the terminal TE(U2) is provided between the diode FWD1 included in the upper arm and the IGBTQ2 included in the lower arm. The terminal TE(U1) of the inverter circuit is coupled to the terminal U of the SR motor, and the terminal TE(U2) of the inverter circuit is coupled to the terminal U′ of the SR motor. The inverter circuit for the SR motor thus configured forms closed circuits, each circuit being comprised of the coils and an H bridge circuit of each phase in the SR motor. Thus, for example, as shown in FIG. 4B, the IGBTQ1 of the upper arm and the IGBTQ2 of the lower arm that are cross-coupled together are turned on, allowing current to pass through the coils between the terminals U-U′ of the SR motor (see the excitation mode of FIG. 3). Thereafter, when the IGBTQ1 and IBGTQ2 are intended to be turned off for the phase conversion, the residual power of the coil needs to be eliminated in the closed circuits described above. However, in this case, the above-mentioned closed circuit does not need to eliminate the residual power of the coil by itself. In the inverter circuit for the SR motor, another closed circuit other than the above-mentioned closed circuit is designed to eliminate the residual power of the coil (demagnetization mode of FIG. 3). That is, in the inverter circuit for the SR motor, as illustrated by the demagnetization mode of FIG. 3, another closed circuit that eliminates the residual power of the coil can be configured not by the IGBTQ1 and IGBTQ2 as the switching elements, but by the diodes FWD1 and FWD2 that are designed to energize the circuit only in the one direction. In this way, the inverter circuit for the SR motor has the feature that the closed circuit in the excitation mode of FIG. 3 is different from the closed circuit in the demagnetization mode of FIG. 3. Because of this feature, as shown in FIG. 4B, the inverter circuit for the SR motor includes two terminals, namely, the terminal TE(U1) and the terminal TE(U2). Thus, the inverter circuit for the SR motor differs from the inverter circuit for the PM motor in that as shown in FIG. 4B, the two terminals, namely, the terminals TE(U1) and TE(U2) are arranged between the upper and lower arms, while as shown in FIG. 4A, one terminal, or terminal TE(U) is arranged between the upper and lower arms.

As mentioned above, due to the difference in the configuration of the inverter circuit, the structure of an electronic device (power module) embodying the inverter circuit for the SR motor in the first embodiment differs from the structure of an electronic device (power module) embodying the inverter circuit for the PM motor. Here, electronic devices embodying the inverter circuits achieve higher performance and downsizing, which are required by the PM motors that are mainly used in the related art, whereas electronic devices for SR motors, which are urgently needed in terms of reduction in cost, cannot achieve the higher performance and downsizing of the electronic device for controlling the SR motor yet. For this reason, the first embodiment of the invention focuses on the SR motor, the need for which has drastically arisen in terms of low cost, and thus devises means for achieving the higher performance and downsizing of an electronic device embodying the inverter circuit for the SR motor and of a semiconductor device as a component of the electronic device. Now, the technical idea of the first embodiment with such devised means will be described. In particular, a main devised means in the first embodiment is directed to a package structure (mounting structure) of a semiconductor device that embodies the inverter circuit for the SR motor, and to a manufacturing method thereof. First, an IGBT and a diode included in the semiconductor device will be described, and then a package structure for the semiconductor device will be described. Thereafter, a method for manufacturing the semiconductor device which is the feature of the first embodiment will be described.

### <Structure of IGBT>

The configuration of the IGBTQ1 and diode FWD1 that are included in the inverter circuit INV of the first embodiment will be described below with reference to the accompanying drawings. The inverter circuit INV in the first embodiment includes the IGBTQ1 and the IGBTQ2, as well as the diode FWD1 and the diode FWD2. Note that since the IGBTQ1 and the IGBTQ2 have the same configuration, and the diode FWD1 and the diode FWD2 have the same configuration, only the IGBTQ1 and the diode FWD1 will be explained below by way of example.

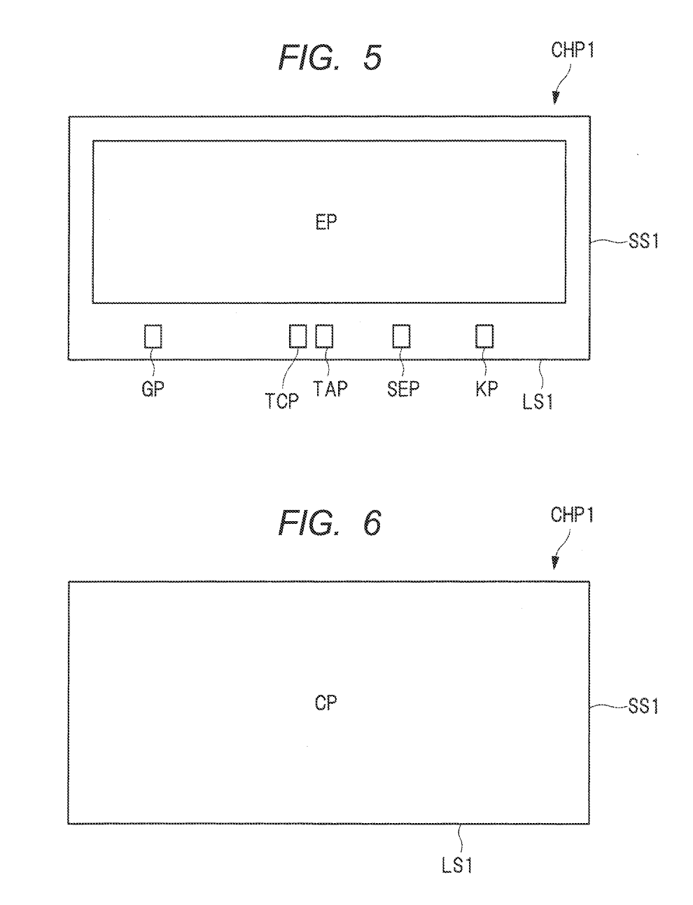

FIG. 5 is a plan view showing an outer appearance of a semiconductor chip CHP1 with the IGBTQ1 formed therein. FIG. 5 illustrates the main surface (front surface) of the semiconductor chip CHP1. As shown in FIG. 5, the semiconductor chip CHP1 in the first embodiment has a rectangular planar shape with a long side LS1 and a short side SS1. An emitter electrode pad EP with a rectangular shape is formed over the front surface of the semiconductor chip CHP1 having the rectangular shape. A plurality of electrode pads is formed along the long side direction of the semiconductor chip CHP1. Specifically, the electrode pads include a gate electrode pad GP, a temperature sensing electrode pad TCP, a temperature sensing electrode pad TAP, a current sensing electrode pad SEP, a kelvin sensing electrode pad KP, which are arranged in that order from the left side of FIG. 5. In this way, the front surface of the rectangular semiconductor chip CHP1 has the emitter electrode pad EP and the electrode pads arranged along its short side direction, the electrode pads being formed along its long side direction. At this time, the size (plane area) of the emitter electrode pad EP is much larger than that of each of the electrode pads.

FIG. 6 is a plan view showing a back surface opposite to the front surface of the semiconductor chip CHP1. As shown in FIG. 6, a collector electrode pad CP having a rectangular shape is formed across the entire back surface of the semiconductor chip CHP1.

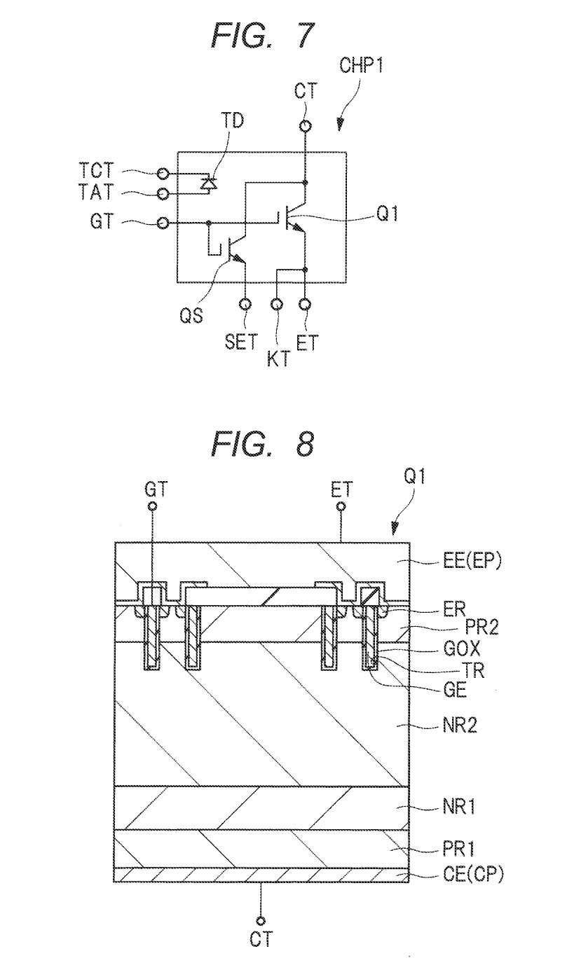

Subsequently, the circuit configuration formed in the semiconductor chip CHP1 will be described below. FIG. 7 shows a circuit diagram of one example of a circuit formed on the semiconductor chip CHP1. As shown in FIG. 7, the semiconductor chip CHP1 has the IGBTQ1, a sensing IGBTQ2, and a temperature sensing diode TD formed thereon. The IGBTQ1 is a main IGBT, and used for driving control of the SR motor MT shown in FIG. 2. The IGBTQ1 includes an emitter electrode, a collector electrode, and a gate electrode formed therein. The emitter electrode of the IGBTQ1 is electrically coupled to an emitter terminal ET via the emitter electrode pad EP shown in FIG. 5. The collector electrode of the IGBTQ1 is electrically coupled to a collector terminal CT via a collector electrode pad CP shown in FIG. 6. The gate electrode of the IGBTQ1 is electrically coupled to a gate terminal GT via the gate electrode pad GP shown in FIG. 5.

The gate electrode of the IGBTQ1 is coupled to the gate control circuit GCC shown in FIG. 2. At this time, a signal from the gate control circuit GCC is applied to the gate electrode of the IGBTQ1 via the gate terminal GT, so that a switching operation of the IGBTQ1 can be controlled by the gate control circuit GCC.

The sensing IGBTQS is provided for sensing an overcurrent passing through between the collector and the emitter of the IGBTQ1. That is, the sensing IGBTQS is provided for protecting the breakage of the IGBTQ1 from the overcurrent by sensing the overcurrent passing through between the collector and the emitter of the IGBTQ1 as the inverter circuit INV. In the sensing IGBTQS, the collector electrode of the sensing IGBTQS is electrically coupled to the collector electrode of the IGBTQ1, and the gate electrode of the sensing IGBTQS is electrically coupled to the gate electrode of the IGBTQ1. The emitter electrode of the sensing IGBTQS is electrically coupled to a current sensing terminal SET other than the emitter electrode of the IGBTQ1 via the current sensing electrode pad SEP shown in FIG. 5. The current sensing terminal SET is coupled to an external current sensing circuit. The current sensing circuit senses current between the collector and emitter of the IGBTQ1 based on an output from the emitter electrode of the sensing IGBTQS. Once overcurrent passes through therebetween, the current sensing circuit inhibits application of a gate signal to the gate electrode of the IGBTQ1, thereby protecting the IGBTQ1 from the overcurrent.

Specifically, the sensing IGBTQS is used as a current sensing element that prevents overcurrent from flowing through the IGBTQ1 due to load short circuit or the like. For example, a current ratio of the current flowing through the main IGBTQ1 to that flowing through the sensing IGBTQS is designed to satisfy the following relationship: IGBTQ1:sensing IGBTQS=1000:1. That is, when a current of 200 A passes through the main IGBTQ1, the sensing IGBTQS permits a current of 200 mA to pass therethrough.

In actual applications, a sense resistor is externally provided to be electrically coupled to the emitter electrode of the sensing IGBTQ2, and a voltage between both ends of the sense resistor is fed back to the control circuit. If the voltage between both ends of the sense resistor is equal to or higher than a preset voltage, the power source is controlled to be interrupted by the control circuit. That is, if the current flowing through the main IGBTQ1 becomes the overcurrent, a current flowing through the sensing IGBTQS is also increased. As a result, the current flowing through the sense resistor is also increased, which increases the voltage between both ends of the sense resistor. It can be confirmed that once the voltage is a preset voltage or more, the current flowing through the main IGBTQ1 is brought into the state of overcurrent.

The temperature sensing diode TD is provided for sensing the temperature of the IGBTQ1 (broadly speaking, the temperature of the semiconductor chip CHP1). That is, the temperature sensing diode TD is designed to change its voltage depending on the temperature of the IGBTQ1, thereby sensing the temperature of the IGBTQ1. The temperature sensing diode TD has a pn junction that is formed by introducing impurities with different conductive types into polysilicon. The temperature sensing diode TD includes a cathode electrode (negative electrode) and an anode electrode (positive electrode). The cathode electrode is electrically coupled to a temperature sensing terminal TCT shown in FIG. 7 by an internal wiring via the temperature sensing electrode pad TCP (see FIG. 5) formed at the upper surface of the semiconductor chip CHP1. Likewise, the anode electrode is electrically coupled to the temperature sensing terminal TAT shown in FIG. 7 by an internal wiring via the temperature sensing electrode pad TAP (see FIG. 5) formed at the upper surface of the semiconductor chip CHP1.

The temperature sensing terminal TCT and the temperature sensing terminal TAT are coupled to a temperature sensing circuit provided outside. The temperature sensing circuit indirectly senses the temperature of the IGBTQ1 based on an output between the temperature sensing terminal TCT and the temperature sensing terminal TAT that are coupled to the cathode electrode and the anode electrode of the temperature sensing diode TD, respectively. Further, the temperature sensing circuit interrupts a gate signal to be applied to the gate electrode of the IGBTQ1 when the sensed temperature reaches a certain temperature or higher, thereby protecting the IGBTQ1.

As mentioned above, the temperature sensing diode TD comprised of the pn junction diode has a feature that drastically increases a forward current flowing through the temperature sensing diode TD when a forward voltage of a certain level or higher is applied to the diode. A voltage at which the forward current starts to drastically flow changes depending on the temperature of the IGBTQ1. When the temperature of the IGBTQ1 increases, the voltage of the diode decreases. The first embodiment takes advantages of this feature of the temperature sensing diode TD. That is, the temperature of the IGBTQ1 can be indirectly monitored by allowing a certain of current to flow through the temperature sensing diode and measuring a voltage between both terminals of the temperature sensing diode TD. In actual applications, the voltage (temperature signal) of the temperature sensing diode TD measured in this way is fed back to the control circuit, so that an element operation temperature is controlled not to exceed a guaranteed value (e.g., of 150° C. to 175° C.).

Referring to FIG. 7, the emitter electrode of the IGBTQ1 is electrically coupled to the emitter terminal ET, and also electrically coupled to the kelvin terminal KT which is a terminal other than the emitter terminal ET. The kelvin terminal KT is electrically coupled to the kelvin sensing electrode pad KP (see FIG. 5) formed at the upper surface of the semiconductor chip CHP1 by an internal wiring. Thus, the emitter electrode of the IGBTQ1 is electrically coupled to the kelvin terminal KT via the kelvin sensing electrode pad KP. The kelvin terminal KT is used as a terminal for sensing the main IGBTQ1. That is, when taking out a sense voltage from the emitter terminal ET of the IGBTQ1 in checking by allowing a large current to flow through the main IGBTQ1, the large current passes through the emitter terminal ET, which inevitably causes a voltage drop due to a wiring resistance, making it difficult to precisely measure an on-voltage. In the first embodiment, the kelvin terminal KT is electrically coupled to the emitter terminal ET of the IGBTQ1, and serves as a voltage sense terminal thorough which a large current does not flow. That is, in checking the large current, the voltage of the emitter electrode is measured from the kelvin terminal KT, so that the on-voltage of the IGBTQ1 can be measured without being influenced by the large current. Further, the kelvin terminal KT is also used as a reference pin for gate drive output that is electrically independent.

As mentioned above, the semiconductor chip CHP1 of the first embodiment can be configured to be coupled to the control circuit, including the current sensing circuit and the temperature sensing circuit or the like, thereby improving the operational reliability of the IGBTQ1 included in the semiconductor chip CHP1.

### <Device Structure of IGBT>

Subsequently, a device structure of the IGBTQ1 will be described. FIG. 8 is a cross-sectional view showing the device structure of the IGBTQ1 in the first embodiment. As shown in FIG. 8, the IGBTQ1 includes a collector electrode CE (collector electrode pad CP) formed at the back surface of the semiconductor chip. A p⁺-type semiconductor region PR1 is formed over the collector electrode CE. An n⁺-type semiconductor region NR1 is formed over the p⁺-type semiconductor region PR1. An n⁻-type semiconductor region NR2 is formed over the n⁺-type semiconductor region NR1. A p-type semiconductor region PR2 is formed over the n⁻-type semiconductor region NR2. Trenches TR are formed to reach the n⁻-type semiconductor region NR2 through the p-type semiconductor region PR2. Further, an n⁺-type semiconductor region ER is formed as an emitter region in alignment with the trench TR. Within the trench TR, a gate insulating film GOX formed of, e.g., a silicon oxide film, is formed. A gate electrode GE is formed in the trench TR via the gate insulating film GOX. The gate electrode GE is formed, for example, of a polysilicon film, to fill the trench TR therewith. FIG. 8 shows the trench gate structure. However, the IGBT device structure is not limited thereto, and may be, for example, an IGBT using a planar gate structure formed over a silicon substrate (not shown).

In the thus-structured IGBTQ1, the gate electrode GE is electrically coupled to the gate terminal GT via the gate electrode pad GP shown in FIG. 5. Likewise, the n⁺-type semiconductor region ER serving as the emitter region is electrically coupled to the emitter terminal ET via an emitter electrode EE (emitter electrode pad EP). The p⁺-type semiconductor region PR1 serving as the collector region is electrically coupled to the collector electrode CE formed at the back surface of the semiconductor chip.

Accordingly, the IGBTQ1 configured in this way has the high-speed switching characteristics and voltage drive characteristics of the power MOSFET, as well as the low on-voltage characteristics of the bipolar transistor.

The n⁺-type semiconductor region NR1 is called a buffer layer. The n⁺-type semiconductor region NR1 is provided to avoid a punch-through phenomenon, that is, to prevent a depletion layer growing from the p-type semiconductor region PR2 into the n⁻-type semiconductor region NR2 from being brought into contact with the p⁺-type semiconductor region PR1 formed under the n⁻-type semiconductor region NR2. Further, the n⁺-type semiconductor region NR1 is also provided to restrict the amount of implantation of holes from the p⁺-type semiconductor region PR1 into the n⁻-type semiconductor region NR2.

### <Operation of IGBT>

Next, the operation of the IGBTQ1 in the first embodiment will be described. First, the operation of turning on the IGBTQ1 will be described. Referring to FIG. 8, a MOSFET with the trench gate structure is turned on by applying a sufficient positive voltage to between the gate electrode GE and the n⁺-type semiconductor region ER serving as the emitter region. In this case, a forward bias is applied to between the p⁺-type semiconductor region PR1 forming the collector region, and the n⁻-type semiconductor region NR2, implanting holes from the p⁺-type semiconductor region PR1 into the n⁻-type semiconductor region NR2. Subsequently, electrons whose charge number is the same as the number of positive charges of the implanted holes are collected in the n⁻-type semiconductor region NR2. In this way, the resistance of the n⁻-type semiconductor region NR2 is reduced (conductivity modulation), thus turning on the IGBTQ1.

A junction voltage between the p⁺-type semiconductor region PR1 and the n⁻-type semiconductor region NR2 is added to the on-voltage, and the resistance value of the n⁻-type semiconductor region NR2 is reduced by more than one digit, namely, by one tenth due to the conductivity modification. In the high breakdown voltage occupying most of the on-resistance, the IGBTQ1 has a lower on-voltage than the power MOSFET. This shows that the IGBTQ1 is a device effective for the high breakdown voltage design. Specifically, in the power MOSFET, to achieve the higher breakdown voltage, it is necessary to increase the thickness of an epitaxial layer serving as a drift layer. In this case, the on-resistance also increases. On the other hand, in the IGBTQ1, even if the thickness of the n⁻-type semiconductor region NR2 is increased to achieve the higher breakdown voltage, the conductivity modification occurs when turning on the IGBTQ1. Thus, in the IGBTQ1, the on-resistance can be reduced as compared to that in the power MOSFET. That is, the IGBTQ1 can achieve a device with a lower on-resistance even when enhancing a breakdown voltage as compared that to in the power MOSFET.

Subsequently, the operation of turning off the IGBTQ1 will be described below. When the voltage between the gate electrode GE and the n⁺-type semiconductor region ER serving as the emitter region is decreased, the MOSFET having the trench gate structure is turned off. In this case, implantation of holes from the p⁺-type semiconductor region PR1 into the n⁻-type semiconductor region NR2 is stopped, and the holes already implanted are diminished due to their lifetime. The remaining holes directly flow into the p⁺-type semiconductor region PR1 (tail current), and then after completion of the outflow, the IGBTQ1 is in an off state. In this way, the IGBTQ1 can be switched between on and off.

### <Structure of Diode>

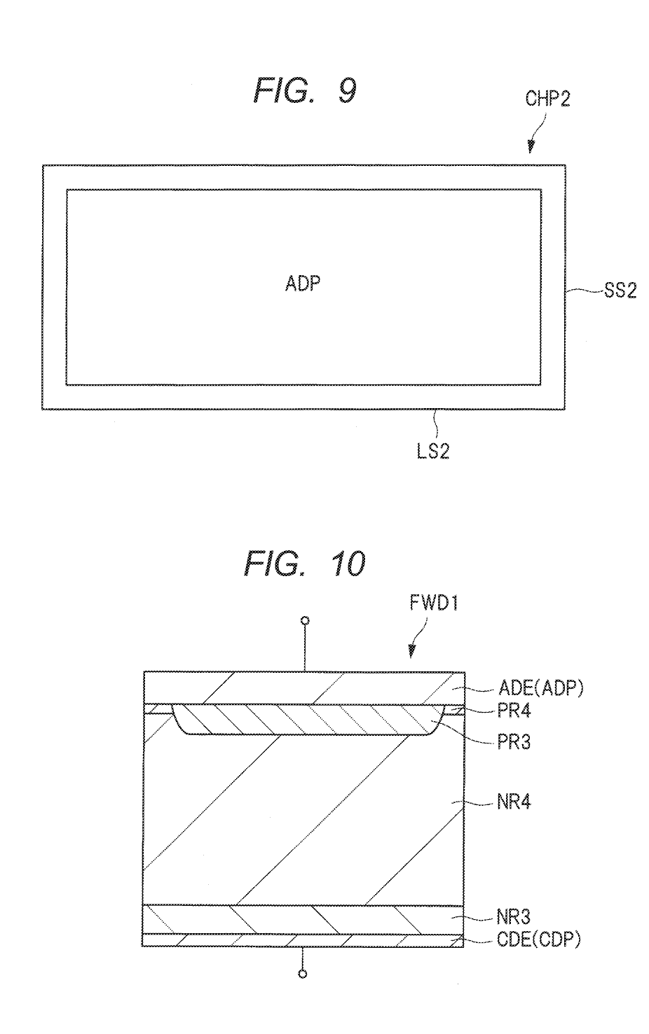

FIG. 9 is a plan view of an outer appearance of a semiconductor chip CHP2 with the diode FWD1 formed therein. FIG. 9 illustrates a main surface (front surface) of the semiconductor chip CHP2. As shown in FIG. 9, the semiconductor chip CHP2 in the first embodiment has a rectangular planar shape with a long side LS2 and a short side SS2. An anode electrode pad ADP having a rectangular shape is formed over the surface of the rectangular semiconductor chip CHP2. On the other hand, a rectangular cathode electrode pad (not shown) is formed across the entire back side opposite to the front surface of the semiconductor chip CHP2.

Subsequently, the device structure of the diode FWD1 will be described. FIG. 10 is a cross-sectional view showing the device structure of the diode FWD1. Referring to FIG. 10, a cathode electrode CDE (cathode electrode pad CDP) is formed at the back surface of the semiconductor chip, and an n⁺-type semiconductor region NR3 is formed over the cathode electrode CDE. Further, an n⁻-type semiconductor region NR4 is formed over the n⁺-type semiconductor region NR3, and a p-type semiconductor region PR3 is formed over the n⁻-type semiconductor region NR4. An anode electrode ADE (anode electrode pad ADP) is formed over the p-type semiconductor region PR3 and the p⁻-type semiconductor region PR4. The anode electrode ADE is formed, for example, of aluminum-silicon.

### <Operation of Diode>

In the diode FWD1 structured in this way, when a positive voltage is applied to the anode electrode ADE, and a negative voltage is applied to the cathode electrode CDE, a forward bias is applied to the pn junction between the n⁻-type semiconductor region NR4 and the p-type semiconductor region PR3, allowing for the flow of current. On the other hand, when a negative voltage is applied to the anode electrode ADE, and a positive voltage is applied to the cathode electrode CDE, a reverse bias is applied to the pn junction between the n⁻-type semiconductor region NR4 and the p-type semiconductor region PR3, interrupting the flow of current. In this way, the diode FWD1 having a rectification function can be operated.

### <Mounting Structure of Semiconductor Device in First Embodiment>

The semiconductor device in the first embodiment is directed to the inverter circuit INV shown in FIG. 2. The semiconductor device is one packaged device including a combination of one IGBT and one diode which are components of the inverter circuit INV. That is, six semiconductor devices of the first embodiment are used to configure an electronic device (power module) with three phase inverter circuits INV for driving three-phase motors.

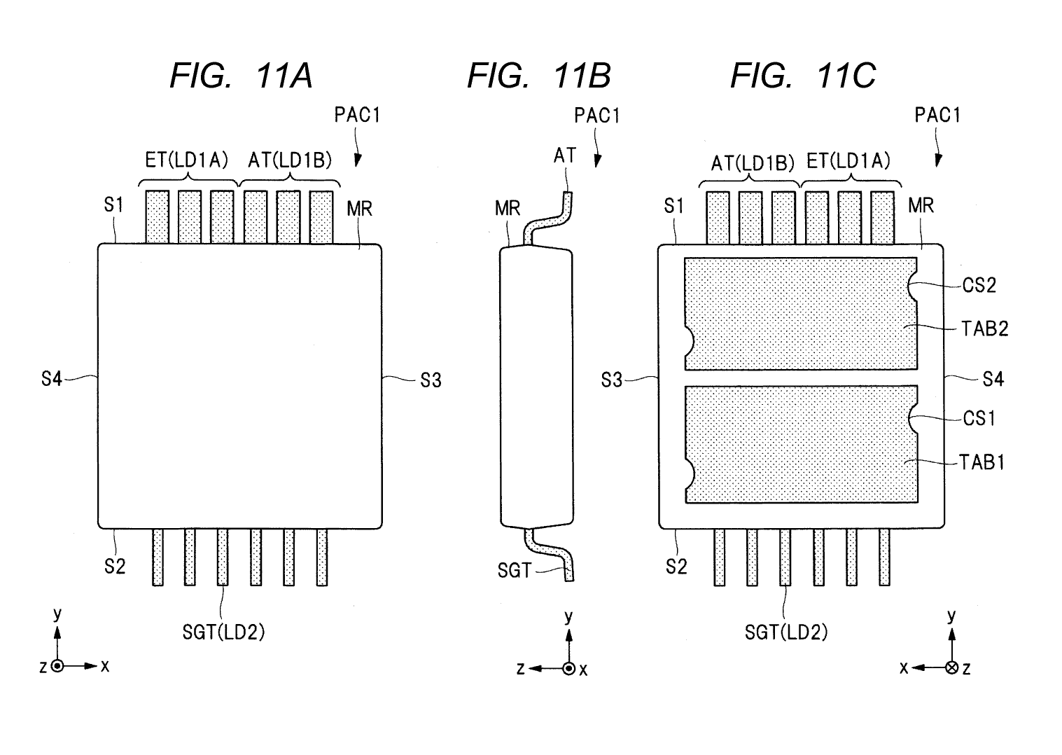

FIGS. 11A, 11B, and 11C are diagrams showing the structure of an outer appearance of the semiconductor device PAC1 in the first embodiment. Specifically, FIG. 11A is a plan view of the semiconductor device PAC1 as viewed from the front surface (upper surface) side thereof in the first embodiment, FIG. 11B is a side view of the semiconductor device PAC1 as viewed from the side surface thereof in the first embodiment, and FIG. 11C is a plan view of the semiconductor device PAC1 as viewed from the back surface (lower surface) side thereof in the first embodiment.

As shown in FIGS. 11A, 11B, and 11C, the semiconductor device PAC1 in the first embodiment has an oblong sealing body MR made of resin. The sealing body MR has an upper surface shown in FIG. 11A, a lower surface opposite to the upper surface and shown in FIG. 11C, a first side surface positioned between the upper surface and the lower surface in the thickness direction, and a second side surface opposed to the first side surface. FIGS. 11A, and 11C illustrate a side S1 serving as the first side surface, as well as a side S2 as the second side surface. The side S1 extends in the x direction, and the side S2 also extends in the x direction. Further, the sealing body MR has a third side surface (see FIG. 11B) intersecting the first and second side surfaces, and a fourth side surface opposed to the third side surface and intersecting the first and second side surfaces. FIGS. 11A and 11C illustrate a side S3 serving as the third side surface, as well as a side S4 serving as the fourth side surface. That is, the sealing body MR has the side S3 extending in the y direction that intersects the x direction, and the side S4 opposed to the side S3.

In the semiconductor device PAC1 of the first embodiment, as shown in FIG. 11, respective parts of leads LD1A and respective parts of leads LD1B protrude from the first side surface, and respective parts of leads LD2 protrude from the second side surface. At this time, the lead LD1A serves as the emitter terminal ET, the lead LD1B serves as the anode terminal AT, and the lead LD2 serves as the signal terminal SGT. In the planar view, the leads LD1A and the leads LD1B are arranged in parallel along the side S1 of the sealing body MR extending in the x direction (first direction). At this time, the width of each of the leads LD1A forming the emitter terminal ET is larger than that of each of the leads LD2 forming the signal terminal SGT. Likewise, the width of each of the leads LD1B forming the anode terminal AT is larger than that of each of the leads LD2 forming the signal terminal SGT. This is because the emitter terminal ET and the anode terminal AT allow for the flow of a large current, which needs to reduce a resistance as much as possible, while the signal terminal SGT allows for the flow of only a slight current. Note that in the semiconductor device PAC1 of the first embodiment, as shown in FIG. 11A, no lead is arranged along the side S3 and the side S4 of the sealing body MR.

As illustrated in FIG. 11C, in the semiconductor device PAC1 of the first embodiment, the chip mounting portions TAB1 and TAB2 are exposed from the back side of the sealing body MR. The chip mounting portion TAB1 and the chip mounting portion TAB2 are physically separated from each other by the sealing body MR. As a result, these chip mounting portions TAB1 and TAB2 are electrically isolated from each other. In other words, the semiconductor device PAC1 of the first embodiment has the chip mounting portions TAB1 and TAB2 that are electrically isolated from each other by the sealing body MR, and the back surface of the chip mounting portion TAB1 and the back surface of the chip mounting portion TAB2 are exposed from the back surface of the sealing body MR. As shown in FIG. 11C, in the semiconductor device PAC1 of the first embodiment, a plurality of cutout portions CS1 is formed in the chip mounting portion TAB1 exposed from the sealing body MR, and a plurality of cutout portions CS2 is formed in the chip mounting portion TAB2 exposed from the sealing body MR.

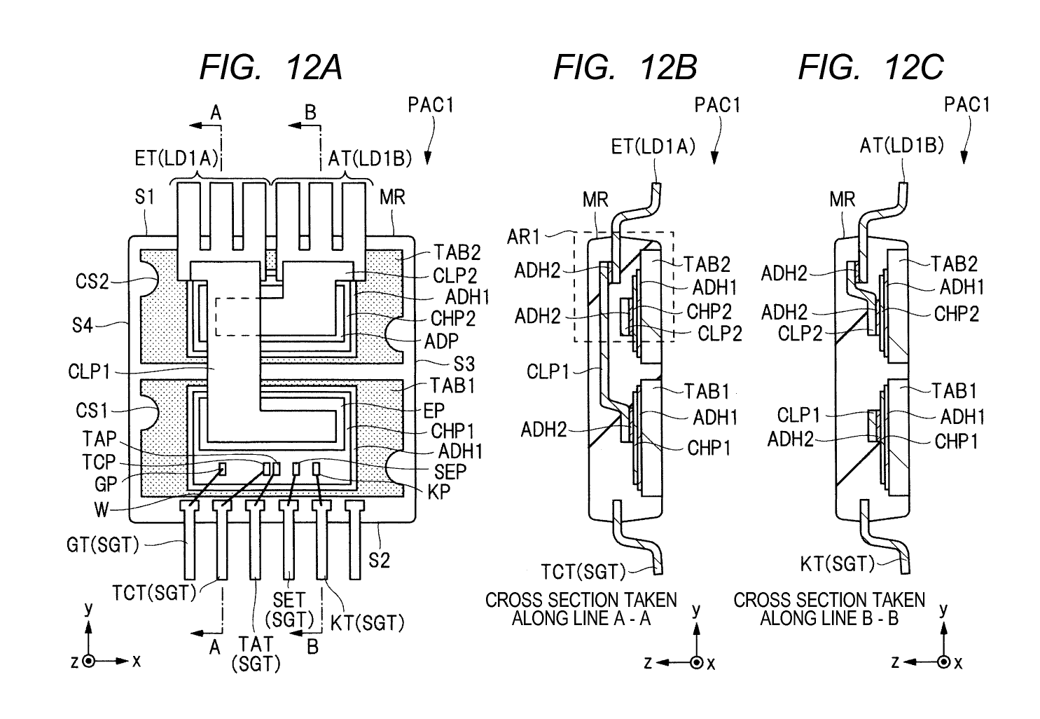

Subsequently, the internal structure of the semiconductor device PAC1 in the first embodiment will be described. FIGS. 12A, 12B, and 12C are diagrams showing the internal structure of the semiconductor device PAC1 in the first embodiment. Specifically, FIG. 12A corresponds to a plan view thereof, FIG. 12B corresponds to a cross-sectional view taken along the line A-A of FIG. 12A, and FIG. 12C corresponds to a cross-sectional view taken along the line B-B of FIG. 12B.

Referring to FIG. 12A, each lead LD1A serving as the emitter terminal ET has a part (first part) sealed by the sealing member MR, and a part (second part) exposed from the sealing member MR. The second parts of the leads LD1A are formed by being divided into a plurality of pieces by slits. Likewise, each lead LD1B serving as the anode terminal AT has a part (third part) sealed by the sealing member MR, and a part (fourth part) exposed from the sealing member MR. The fourth parts of the leads LD1B are formed by being divided into a plurality of pieces by slits.

Referring to FIG. 12A, the oblong or rectangular chip mounting portion TAB1 and the oblong or rectangular chip mounting portion TAB2 are arranged within the sealing body, and separated from each other. These chip mounting portions TAB1 and TAB2 also function as a heat spreader that enhances a heat dissipation efficiency, and are formed of a material that contains copper having high heat conductivity as a principal element, for example. At this time, as shown in FIG. 12A, in the semiconductor device PAC1 of the first embodiment, cutout portions CS1 are formed in the chip mounting portion TAB1, and cutout portions CS2 are formed in the chip mounting portion TAB2.

Here, the term “principle element” as used in the present specification means a material component that is contained most among components included in a member. For example, the “material containing copper as a principle element” means that the material of the member contains copper most. It is intended that the term “principle element” as used in the present specification means, for example, the member is basically comprised of copper, but does not exclude the case in which other impurities are also included in the member.

The semiconductor chip CHP1 with the IGBT formed therein is mounted over the chip mounting portion TAB1 via a conductive adhesive ADH1. At this time, the surface with the semiconductor chip CHP1 mounted over is defined as a first upper surface of the chip mounting portion TAB1, and a surface opposite to the first upper surface is defined as a first lower surface. In this case, the semiconductor chip CHP1 is mounted over the first upper surface of the chip mounting portion TAB1. Specifically, the semiconductor chip CHP1 with the IGBT formed therein is positioned such that the collector electrode CE (collector electrode pad CP) formed at the back surface of the semiconductor chip CHP1 (see FIGS. 6 and 8) is in contact with the first upper surface of the chip mounting portion TAB1 via the conductive adhesive ADH1. In this case, the emitter electrode EP and the electrode pads that are formed at the front surface of the semiconductor chip CHP1 are faced upward.

The semiconductor chip CHP2 with the diode formed thereon is mounted over the chip mounting portion TAB2 via a conductive adhesive ADH1. At this time, the surface with the semiconductor chip CHP2 mounted over is defined as a second upper surface of the chip mounting portion TAB2, and a surface opposite to the second upper surface is defined as a second lower surface. In this case, the semiconductor chip CHP2 is mounted over the second upper surface of the chip mounting portion TAB2. Specifically, the semiconductor chip CHP2 with the diode formed therein is positioned such that the cathode electrode pad formed at the back surface of the semiconductor chip CHP2 is in contact with the second upper surface of the chip mounting portion TAB2 via the conductive adhesive ADH1. In this case, the anode electrode pad ADP formed at the front surface of the semiconductor chip CHP2 are faced upward. Thus, in the semiconductor device PAC1 of the first embodiment, the chip mounting portion TAB1 and the chip mounting portion TAB2 are electrically separated from each other. In this way, the collector electrode CE (collector electrode pad CP) of the semiconductor chip CHP1 in contact with the first upper surface of the chip mounting portion TAB1 (see FIGS. 6 and 8), and the cathode electrode pad of the semiconductor chip CHP2 in contact with the second upper surface of the chip mounting portion TAB2 are electrically separated from each other.

Note that as shown in FIG. 12A, the plane area of the chip mounting portion TAB1 is larger than that of the semiconductor chip CHP1 with the IGBT formed therein, and the plane area of the chip mounting portion TAB2 is larger than that of the semiconductor chip CHP2 with the diode formed therein.

Subsequently, as shown in FIG. 12A, a clip CLP1 which is formed of a conductive material is arranged over the emitter electrode pad EP of the semiconductor chip CHP1 via a conductive adhesive. The clip CLP1 is coupled to the emitter terminal ET via the conductive adhesive. Therefore, the emitter electrode pad EP of the semiconductor chip CHP1 is electrically coupled to the emitter terminal ET via the clip CLP1. The clip CLP1 is a plate-shaped member formed, for example, of copper as a principal component. That is, in the first embodiment, a large current flows from the emitter electrode pad EP to the emitter terminal ET in the semiconductor chip CHP1. For this reason, the clip CLP1 that can ensure its large area is used to allow for the flow of a large current.

As shown in FIG. 12A, a plurality of electrode pads is formed at the surface of the semiconductor chip CHP1. Each of the electrode pads is electrically coupled to the corresponding signal terminal SGT by a wire W which is a conductive member. Specifically, the electrode pads include a gate electrode pad GP, a temperature sensing electrode pad TCP, a temperature sensing electrode pad TAP, a current sensing electrode pad SEP, and a kelvin sensing electrode pad KP. The gate electrode pad GP is electrically coupled to the gate terminal GT, which is one of the signal terminals SGT, by the wire W. Likewise, the temperature sensing electrode pad TCP is electrically coupled to the temperature sensing terminal TCT as one of the signal terminals SGT by the wire W. The temperature sensing electrode pad TAP is electrically coupled to the temperature sensing terminal TAT as one of the signal terminals SGT by the wire W. The temperature sensing electrode pad SEP is electrically coupled to the temperature sensing terminal SET as one of the signal terminals SGT by the wire W. The kelvin sensing electrode pad KP is electrically coupled to the kelvin terminal KT by the wire W. At this time, the wire W is formed of a conductive material that contains, for example, gold, copper, or aluminum as a principle element.

On the other hand, as shown in FIG. 12A, a clip CLP2 as a conductive member is arranged over the anode electrode pad ADP of the semiconductor chip CHP2 via a conductive adhesive. The clip CLP2 is coupled to the anode terminal AT via the conductive adhesive. Therefore, the anode electrode pad ADP of the semiconductor chip CHP2 is electrically coupled to the anode terminal AT via the clip CLP2. The clip CLP2 is a plate-shaped member, for example, formed of copper as a principal component. That is, in the first embodiment, a large current flows from the anode electrode pad ADP to the anode terminal AT in the semiconductor chip CHP2. For this reason, the clip CLP2 that can ensure its large area is used to allow for the flow of a large current.

Here, as shown in FIG. 12A, in the planar view, the chip mounting portion TAB2 is arranged between the side S1 (see FIG. 11A) of the sealing body MR and the chip mounting portion TAB1. Thus, the semiconductor chip CHP2 is mounted over the chip mounting portion TAB2 so as to be positioned between the semiconductor chip CHP1 and the emitter terminal ET (and anode terminal AT). The semiconductor chip CHP1 is mounted over the chip mounting portion TAB1 so as to be positioned between the semiconductor chip CHP2 and the signal terminal SGT.

In other words, the emitter terminal ET and anode terminal AT, the semiconductor chip CHP2, the semiconductor chip CHP1, and the signal terminal SGT are arranged along the y direction. Specifically, in the planar view, the semiconductor chip CHP2 is mounted over the chip mounting portion TAB2 so as to be positioned closer to the emitter terminal ET and anode terminal AT than the semiconductor chip CHP1. The semiconductor chip CHP1 is mounted over the chip mount portion TAB1 so as to be positioned closer to the signal terminal SGT than the semiconductor chip CHP2.

In the planar view, the semiconductor chip CHP1 is mounted over the chip mounting portion TAB1 such that the gate electrode pad GP is positioned closer to the signal terminal SGT than the emitter electrode pad EP. Further, the semiconductor chip CHP1 is mounted over the chip mounting portion TAB1 such that the electrode pads, including the gate electrode pad GP, the temperature sensing electrode pad TCP, the temperature sensing electrode pad TAP, the current sensing electrode pad SEP, and the kelvin sensing electrode pad KP are closer to the signal terminal SGT than the emitter electrode pad EP in the planar view. In other words, it can be said that the electrode pads of the semiconductor chip CHP1 are arranged along the side that is located closest to the signal terminal SGT among the sides of the semiconductor chip CHP1 in the planar view. At this time, as shown in FIG. 12A, the clip CLP1 is arranged not to overlap with both the wires W and the electrode pads including the gate electrode pad GP in the planar view.

Referring to FIG. 12A, the clip CLP1 and the clip CLP2 are electrically isolated from each other. In consideration of electrical isolation between the chip mounting portions TAB1 and TAB2, and another electrical isolation between the clips CLP1 and CLP2, the semiconductor device PAC1 in the first embodiment allows for the electrical isolation between the emitter terminal ET and the anode terminal AT.

The clip CLP1 is arranged to overlap with the semiconductor chip CHP2 in the planar view. Specifically, as shown in FIG. 12A, the anode electrode pad ADP of the semiconductor chip CHP is formed over the surface of the semiconductor chip CHP2 to partially overlap with the clip CLP1 in the planar view, and the clip CLP2 is electrically coupled to the anode electrode pad ADP to cover the anode electrode pad ADP. Thus, the clip CLP1 is arranged to overlap with a part of the clip CLP2 positioned over the anode electrode pad ADP.

In the semiconductor device PAC1 having the internal structure described above, the semiconductor chip CHP1, the semiconductor chip CHP2, a part of the chip mounting portion TAB1, a part of the chip mounting portion TAB2, parts of the leads LD1A, parts of the leads LD1B, parts of the respective signal terminals SGT, the clips CLP1 and CLP2, and the wires W are sealed with the sealing body MR.

Subsequently, as shown in FIGS. 12B and 12C, the semiconductor chip CHP1 with the IGBT formed therein is mounted over the chip mounting portion TAB1 via the conductive adhesive ADH1, and the semiconductor chip CHP2 with the diode formed therein is mounted over the chip mounting portion TAB2 via the conductive adhesive ADH1.

As illustrated in FIG. 12B, the clip CLP1 is arranged over the surface of the semiconductor chip CHP1 via the conductive adhesive ADH2. The clip CLP1 extends over the semiconductor chip CHP2, and is coupled to the emitter terminal ET via the conductive adhesive ADH2. Apart of the emitter terminal ET is exposed from the sealing body MR. The semiconductor chip CHP1 is coupled to the signal terminal SGT arranged opposite to the emitter terminal ET, by the wire W with parts of the signal terminals SGT exposed from the sealing body MR.

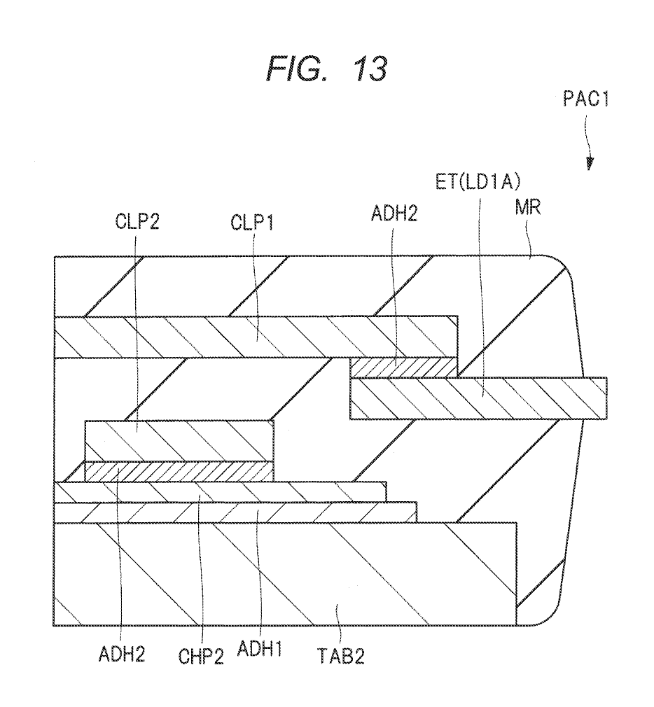

FIG. 13 is an enlarged view of a region AR1 of FIG. 12B. As shown in FIG. 13, the clip CLP1 extends over the clip CLP2 mounted over the semiconductor chip CHP2 via the conductive adhesive ADH2. That is, as shown in FIG. 13, the clip CLP1 is arranged to cross a part of the clip CLP2 while being spaced apart from the clip CLP2. As can be seen from this description, the clip CLP1 and the clip CLP2 are physically separated from each other, resulting in electrical isolation between the clips CLP1 and CLP2.

As illustrated in FIG. 12C, the clip CLP2 is arranged over the surface of the semiconductor chip CHP2 via the conductive adhesive ADH2. The clip CLP2 is coupled to the anode terminal AT via the conductive adhesive ADH2, and a part of the anode terminal AT is exposed from the sealing body MR.

As shown in FIGS. 12B and 12C, the lower surface of the chip mounting portion TAB1 is exposed from the lower surface of the sealing body MR. The exposed lower surface of the chip mounting portion TAB1 serves as the collector terminal. When the semiconductor device PAC1 is mounted on the mounting substrate, the lower surface of the chip mounting portion TAB1 becomes a surface that can be soldered to the wires formed on the mounting substrate.

Similarly, the lower surface of the chip mounting portion TAB2 is exposed from the lower surface of the sealing body MR. The exposed lower surface of the chip mounting portion TAB2 serves as the cathode terminal. When the semiconductor device PAC1 is mounted on the mounting substrate, the lower surface of the chip mounting portion TAB2 becomes a surface that can be soldered to the wires formed on the mounting substrate.

At this time, as shown in FIGS. 12B and 12C, the chip mounting portion TAB1 and the chip mounting portion TAB2 are electrically isolated from each other, resulting in electrical isolation between the collector terminal as the lower surface of the chip mounting portion TAB1 and the cathode terminal as the lower surface of the chip mounting portion TAB2.

Note that as illustrated in FIGS. 12B and 12C, the thickness of each of the chip mounting portion TAB1 and the chip mounting portion TAB2 is larger than that of each of the emitter terminal ET, the anode terminal AT, and the signal terminal SGT.

In the semiconductor device PAC1 of the first embodiment, for example, a silver paste containing a silver filler (Ag filler) and a binder containing a material, such as epoxy resin, can be used as the conductive adhesive ADH1 and the conductive adhesive ADH2. The silver paste has the advantage of eco-friendly material as it is a lead-free material that does not contain lead as a component. The silver paste further has the advantage that it can improve the reliability of the semiconductor device PAC1 because of its excellent temperature cycle characteristics and power cycle characteristics. In use of the silver paste, the silver paste can be subjected to a heat treatment in a low-cost baking furnace, for example, as compared to a vacuum reflow device used in a reflow process of solder, which can provide an assembly equipment of the semiconductor device PAC1 at low cost.

Note that it is obvious that in addition to the silver paste, for example, a solder material can also be used as material for the conductive adhesive ADH1 and the conductive adhesive ADH2. When using a solder material as the material for the conductive adhesives ADH1 and ADH2, the on-resistance of the semiconductor device PAC1 can be advantageously reduced because of a high electric conductivity of the solder material. That is, the use of the solder material can improve the performance of the semiconductor device PAC1 used in an inverter that requires the reduction in on-resistance.

After completion of the semiconductor device PAC1 as a product in the first embodiment, the semiconductor device PAC1 is mounted on a circuit board (mounting substrate). In this case, the semiconductor device PAC1 is coupled to the mounting substrate with the solder. In coupling with the solder, a heating process (reflow) is needed to melt the solder material for coupling.

Thus, when the solder material used for coupling the semiconductor device PAC1 to the mounting substrate is the same as that used in the above-mentioned semiconductor device PAC1, the heat treatment (reflow) applied for coupling between the semiconductor device PAC1 and the mounting substrate also melts the solder material used in the semiconductor device PAC1. In this case, disadvantageously, the resin sealing the semiconductor device PAC1 might get cracks due to volume expansion of the solder material melted, or the melted solder material might leak to the outside.

For this reason, a high-melting-point solder material is used inside the semiconductor device PAC1. In this case, the heat treatment (reflow) applied for coupling between the semiconductor device PAC1 and the mounting substrate does not melt the high-melting-point solder material that is used inside the semiconductor device PAC1. As a result, this arrangement can prevent the disadvantages, including generation of cracks in a resin sealing the semiconductor device PAC1 due to volume expansion caused by melting the high-melting-point solder material, and the leakage of the melted solder material to the outside.

The solder material used for coupling between the semiconductor device PAC1 and the mounting substrate is one having a high melting point of about 220° C., and typified, for example, by Sn (tin)-Ag (silver)-Cu (copper). At the time of reflow, the semiconductor device PAC1 is heated to approximately 260° C. This means that, for example, the term “high-melting-point solder” as used in the present specification is a solder material that does not melt even if it is heated to about 260° C. For example, a typical solder material is one having a melting point of 300° C. or higher, a reflow temperature of approximately 350° C., and containing 90% by weight Pb (lead).

Basically, in the semiconductor device PAC1 of the first embodiment, the conductive adhesive ADH1 and the conductive adhesive ADH2 are supposed to be formed of the same components. Note that the semiconductor device of the invention is not limited thereto. Alternatively, for example, material for the conductive adhesive ADH1 and material for the conductive adhesive ADH2 can also be formed of different components.

<Structure with Stepped Portion at Side Surface>

Subsequently, the “structure with a stepped portion at its side surface” that the semiconductor device PAC1 in the first embodiment has will be described below.

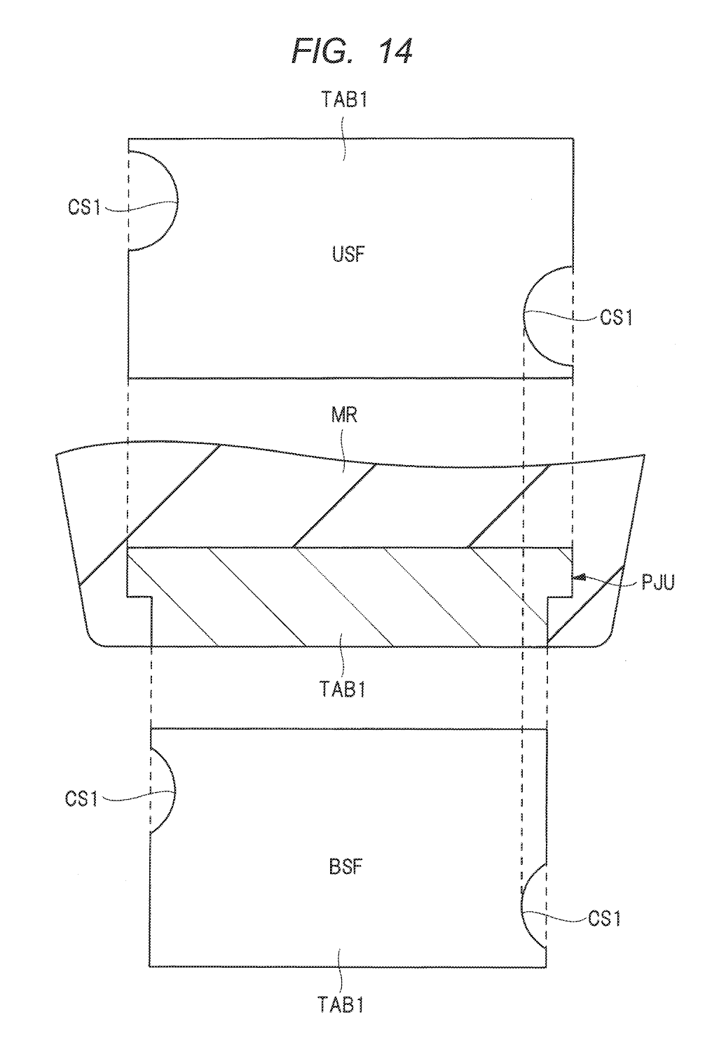

FIG. 14 is a diagram for explaining the “structure with a stepped portion at its side surface”. FIG. 14 schematically shows at its center, a state of the chip mounting portion TAB1 having the “structure with a stepped portion at its side surface” sealed with the sealing body MR. Referring to FIG. 14, the sealing body MR is formed to cover the chip mounting portion TAB1 with the lower surface of the chip mounting portion TAB1 exposed from the back surface of the sealing body MR.

At this time, as shown in FIG. 14, “projections PJU” are formed at the chip mounting portion TAB1. That is, the end (or side surface) of the chip mounting portion TAB1 is provided with the projection PJU to produce a stepped portion in the thickness direction of the chip mounting portion TAB1. The stepped structure with the projection PJU serves as a stopper, which can advantageously prevent the chip mounting portion TAB1 from falling off the sealing body MR.

With the stepped structure, the area of the upper surface USF of the chip mounting portion TAB1, shown in the upper part of FIG. 14 is set larger than that of the lower surface BSF of the chip mounting portion TAB1 exposed from the back surface of the sealing body MR, shown in the lower part of FIG. 14. In other words, with the stepped structure, the area of the lower surface BSF of the chip mounting portion TAB1 exposed from the back surface of the sealing body MR, shown in the lower part of FIG. 14 is set smaller than that of the upper surface USF of the chip mounting portion TAB1, shown in the upper part of FIG. 14.

Note that FIG. 14 illustrates the stepped structure by focusing on the chip mounting portion TAB1, but the end (or side surface) of the chip mounting portion TAB2 can also be provided with another stepped structure created by the projection PJU in the same way. Thus, also in the chip mounting portion TAB2, with the stepped structure, the area of the upper surface of the chip mounting portion TAB2 is set larger than that of the lower surface of the chip mounting portion TAB2 exposed from the back surface of the sealing body MR.

Here, in the semiconductor device PAC1 of the first embodiment, the cutout portions CS1 are formed in the chip mounting portion TAB1. However, for example, when the cutout portions CS1 are formed to reach the upper surface UF and lower surface BSF of the chip mounting portion TAB1, as shown in FIG. 14, with the stepped structure created by the projections PJU, the area of the cutout portion CS1 at the upper surface USF of the chip mounting portion TAB1 is set larger than that of the cutout portion CS1 at the lower surface BSF of the chip mounting portion TAB1. In detail, in the planer view, the area of a region formed between the cutout portion CS1 on the side of the upper surface USF of the chip mounting portion TAB1, shown in the upper part of FIG. 14, and a virtual line of a corresponding one of the sides of the upper surface USF of the chip mounting portion TAB1 with the cutout portion CS1 formed therein is larger than that of a region formed between the cutout portion CS1 on the side of the lower surface BSF of the chip mounting portion TAB1, shown in the lower part of FIG. 14, and a virtual line of a corresponding one of the sides of the lower surface BSF of the chip mounting portion TAB1 with the cutout portion CS1 formed therein.

Likewise, in the semiconductor device PAC1 of the first embodiment, the cutout portions CS2 are formed in the chip mounting portion TAB2. However, for example, when the cutout portions CS2 are formed to reach the upper surface and lower surface of the chip mounting portion TAB2, with the stepped structure created by the projections PJU, the area of the cutout portion CS2 at the upper surface of the chip mounting portion TAB2 is set larger than that of the cutout portion CS2 at the lower surface of the chip mounting portion TAB2.

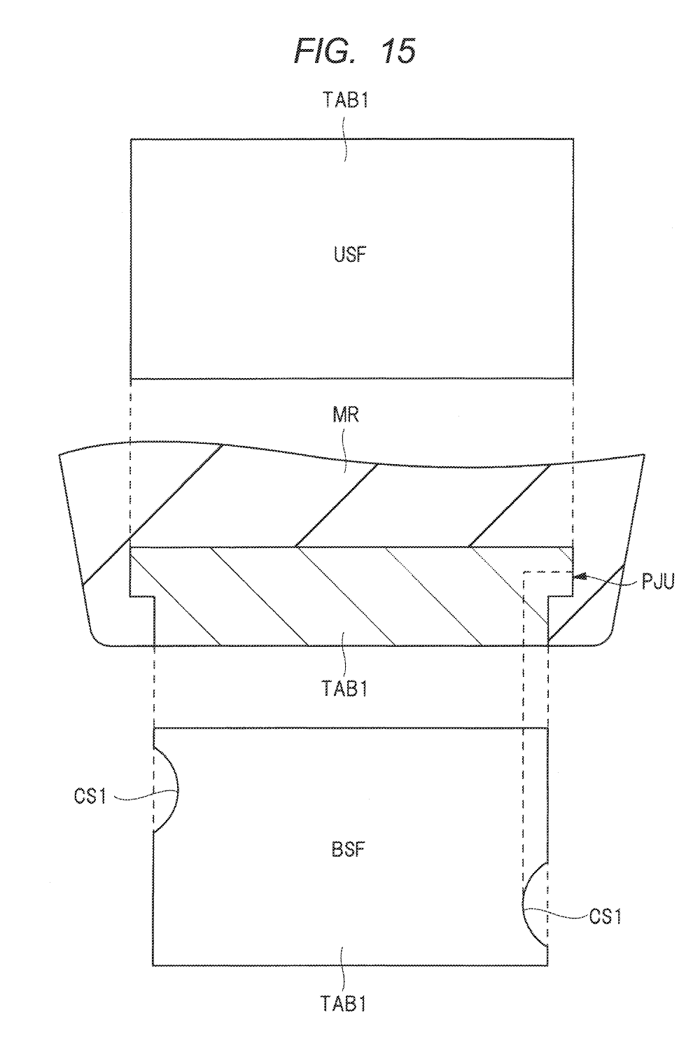

For example, as shown in FIG. 15, the cutout portion CS1 may be formed not to reach the upper surface of the chip mounting portion TAB1, but to reach only the lower surface BSF.

In this case, as shown in FIG. 15, the cutout portion CS1 is not formed at the upper surface USF of the chip mounting portion TAB1, while the cutout portion CS1 is formed at the lower surface BSF of the chip mounting portion TAB1.

Likewise, the cutout portion CS2 in the chip mounting portion TAB2 can also be formed not to reach the upper surface of the chip mounting portion TAB2, but to reach only the lower surface thereof. In this case, the cutout portion CS2 is not formed at the upper surface of the chip mounting portion TAB2, while the cutout portion CS2 is formed at the lower surface BSF of the chip mounting portion TAB2.

In the way described above, the semiconductor device PAC1 in the first embodiment is mounted. Now, a description will be given of a method for manufacturing the semiconductor device PAC1 in the first embodiment with reference to the accompanying drawings.

### <Method for Manufacturing a Semiconductor Device in the First Embodiment>

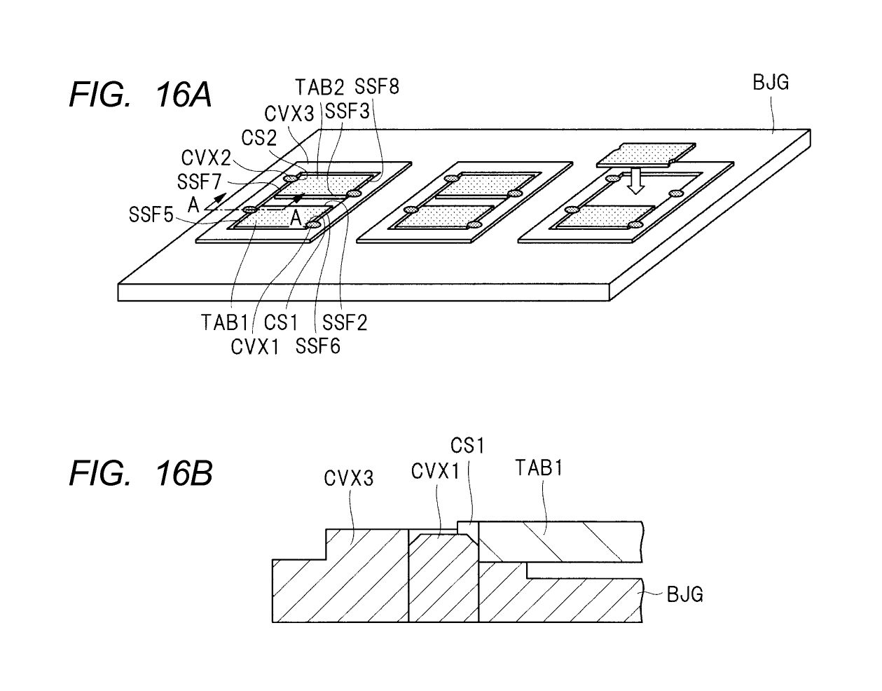

1. Chip Mounting Portion Provision Step As shown in FIG. 16A, first, the lower jig BJG having a main surface with a plurality of convex portions CVX1 and a plurality of convex portions CVX2 is provided. At this time, a convex portion CVX3 is formed around the convex portions CVX1 and the convex portions CVX2 over the main surface of the lower jig BJG.

After providing the lower jig BJG structured in this way, the chip mounting portions TAB1 and TAB2 are arranged over the main surface of the lower jig BJG. Specifically, as shown in FIG. 16A, the chip mounting portion TAB1 and the chip mounting portion TAB2 are arranged over the main surface of the lower jig BJG such that the side surface SSF2 of the chip mounting portion TAB1 faces the side surface SSF3 of the chip mounting portion TAB2. At this time, as shown in FIG. 16A, the upper surface of the chip mounting portion TAB1 has a rectangular planar shape, and the upper surface of the chip mounting portion TAB2 also has a rectangular planar shape. The side surface SSF2 of the chip mounting portion TAB1 is a side surface including a long side that forms the upper surface of the chip mounting portion TAB1, and the side surface SSF3 of the chip mounting portion TAB2 is aside surface including a long side that forms the upper surface of the chip mounting portion TAB2.

Here, as shown in FIG. 16A, side surfaces of the chip mounting portion TAB1 other than the side surface SSF2 are pressed against the respective convex portions CVX1, thereby positioning the chip mounting portion TAB1 over the main surface of the lower jig BJG. Likewise, side surfaces of the chip mounting portion TAB2 other than the side surface SSF3 are pressed against the respective convex portions CVX2, thereby positioning the chip mounting portion TAB2 over the main surface of the lower jig BJG.

In more detail, as shown in FIG. 16A, the chip mounting portion TAB1 and the chip mounting portion TAB2 have the quadrilateral planar shape. The chip mounting portion TAB1 has side surfaces SSF5 and SSF6 that are opposed to each other, while intersecting the side surface SSF2. The chip mounting portion TAB2 has side surfaces SSF7 and SSF8 that are opposed to each other, while intersecting the side surface SSF3. At this time, for example, the convex portions CVX1 are arranged in contact with only the side surfaces SSF5 and SSF6, and the convex portions CVX2 are arranged in contact with only the side surfaces SSF7 and SSF8.

The side surfaces SSF5 and SSF6 of the chip mounting portion TAB1 have the cutout portions CS1 corresponding to the respective convex portions CVX1. Likewise, the side surfaces SSF7 and SSF8 of the chip mounting portion TAB2 have the cutout portions CS2 corresponding to the respective convex portions CVX2.

Specifically, as shown in FIG. 16A, each of the side surfaces SSF5 and SSF6 of the chip mounting portion TAB1 is provided with at least one cutout portion CS1 corresponding to one of the convex portions CVX1, and each of the side surfaces SSF7 and SSF8 of the chip mounting portion TAB2 is provided with at least one cutout portion CS2 corresponding to one of the convex portions CVX2.

Thus, in the first embodiment, the cutout portions CS1 formed in the chip mounting portion TAB1 are pressed against the convex portions CVX1, thereby positioning the chip mounting portion TAB1 at the main surface of the lower jig BJG. Further, the cutout portions CS2 formed in the chip mounting portion TAB2 are pressed against the convex portions CVX2, thereby positioning the chip mounting portion TAB2 at the main surface of the lower jig BJG.

Note that the chip mounting portion TAB1 and the chip mounting portion TAB2 can have, for example, an oblong or rectangular shape with the same size. At this time, the size of the chip mounting portion TAB1 and the size of the chip mounting portion TAB2 do not need to have the same size, and may have different sizes. In the semiconductor device for the SR motor, heat loss in the IGBT is substantially equal to that in the diode. Thus, it is desirable that the heat dissipation efficiency from the semiconductor chip with the IGBT formed therein is set equal to that from the semiconductor chip with the diode formed therein. For this reason, the size of the chip mounting portion TAB1 on which the semiconductor chip with the IGBT is mounted is set substantially equal to that of the chip mounting portion TAB2 on which the semiconductor chip with the diode is mounted, whereby the heat dissipation efficiency from both semiconductor chips can be set to the same level, which is desirable in view of improving the heat dissipation efficiency of the entire semiconductor device.

FIG. 16B is a cross-sectional view taken along the line A-A of FIG. 16A. As shown in FIG. 16B, the lower jig BJG is provided with the convex portion CVX3. The convex portion CVX1 is formed to be in contact with the convex portion CVX3. The cutout portion CS1 formed in the chip mounting portion TAB1 is pressed against the convex portion CVX1, thereby positioning the chip mounting portion TAB1 over the lower jig BJG.

Here, as shown in FIG. 16B, with the main surface of the lower jig BJG defined as a reference surface, the height of the convex portion CVX3 is higher than that of the convex portion CVX1, and lower than that of the upper surface of the chip mounting portion TAB1. Likewise, although not shown in FIG. 16B, the height of the convex portion CVX3 is higher than that of the convex portion CVX2, and lower than that of the upper surface of the chip mounting portion TAB2. As a result, a conductive adhesive formation step to be described below can be easily performed. Now, the conductive adhesive formation step will be described.

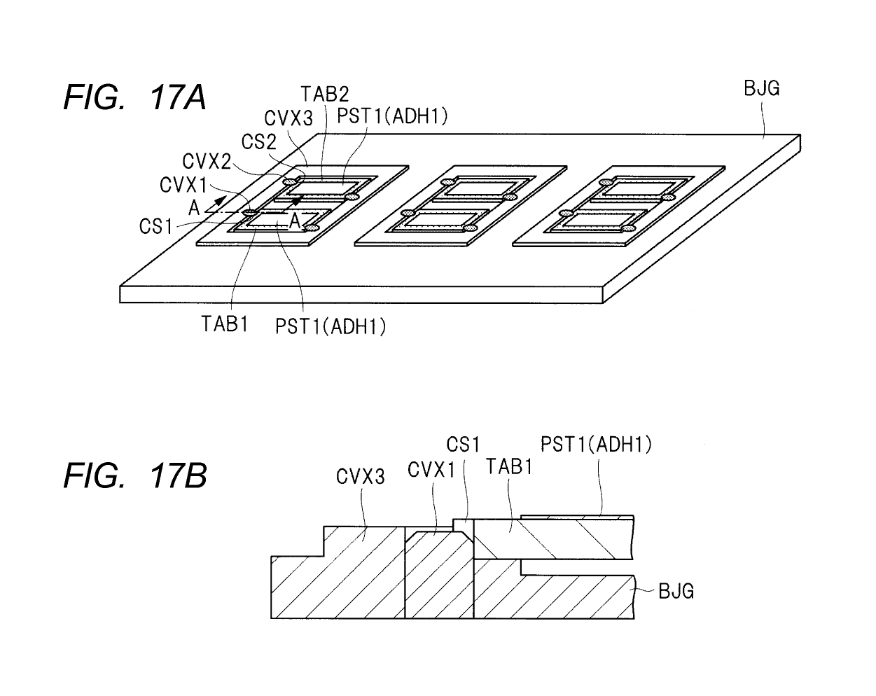

2. Conductive Adhesive Formation Step As shown in FIGS. 17A and 17B, the conductive adhesive ADH1 is supplied over the chip mounting portion TAB1, and the conductive adhesive ADH1 is also supplied over the chip mounting portion TAB2. Suitable materials for the conductive adhesive ADH1 can include, for example, a silver paste, and a solder (solder paste) having a high melting point. In the following, a conductive paste PST1 will be described by way of example of the conductive adhesive ADH1.

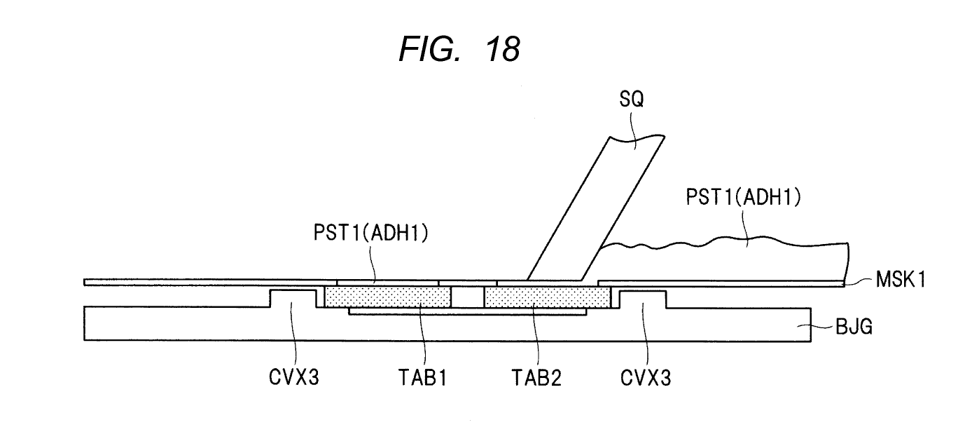

FIG. 18 is an exemplary diagram of a step of forming the conductive paste PST1 over the chip mounting portion TAB1 and the chip mounting portion TAB2. Referring to FIG. 18, first, a printing mask MSK1 is arranged over the main surface of the lower jig BJG so as to be positioned above the upper surface of the chip mounting portion TAB1 and the upper surface of the chip mounting portion TAB2.

At this time, as shown in FIG. 16B described above, with the main surface of the lower jig BJG set as a reference surface, the height of the convex portion CVX3 is higher than that of the convex portion CVX1, and lower than that of the upper surface of the chip mounting portion TAB1, and the height of the convex portion CVX3 is higher than that of the convex portion CVX2, and lower than the upper surface of the chip mounting portion TAB2.

As a result, the printing mask MSK1 can be arranged over the main surface of the lower jig BJG such that the back surface of the printing mask MSK1 is in contact with the upper surface of the chip mounting portion TAB1 and the upper surface of the chip mounting portion TAB2, while maintaining a gap from the convex portion CVX3.

Thereafter, as shown in FIG. 18, the conductive paste PST1 is squeegeeing by a squeegee SQ over the surface of the printing mask MSK1, and then from an opening formed in the printing mask MSK1, and the conductive paste PST1 is supplied over the upper surface of the chip mounting portion TAB1 and the upper surface of the chip mounting portion TAB2. At this time, the height of the convex portion CVX3 is set such that the squeegee SQ passes through over the convex portion CVX3 in the squeegee step, and that once the printing mask MSK1 is bent, the back surface of the printing mask MSL1 is in contact with the convex portion CVX3. Thus, in the first embodiment, the mask MSK1 can be held by the convex portion CVX3 formed in the lower jig BJG in the squeegee step, which makes the levelness of the printing mask MSK1 constant. In this way, an unnecessary part of the conductive paste PST1 can be removed by the squeegee SQ, while supplying the conductive paste PST1 over the upper surface of the chip mounting portion TAB1 as well as the upper surface of the chip mounting portion TAB2, these upper surfaces being exposed from the opening of the printing mask MSK1.

In the first embodiment, the convex portion CVX3 is formed at the lower jig BJG in this way, so that the conductive paste PST1 can be supplied over the upper surfaces of the chip mounting portions TAB1 and TAB2, while positioning the chip mounting portions TAB1 and TAB2 by the lower jig BJG. That is, the convex portion CVX3 formed in the lower jig BJG serves to easily perform the squeegeeing step of supplying the conductive paste PST1 over the upper surfaces of the chip mounting portions TAB1 and TAB2, by using the printing mask MSK1 and the squeegee SQ.

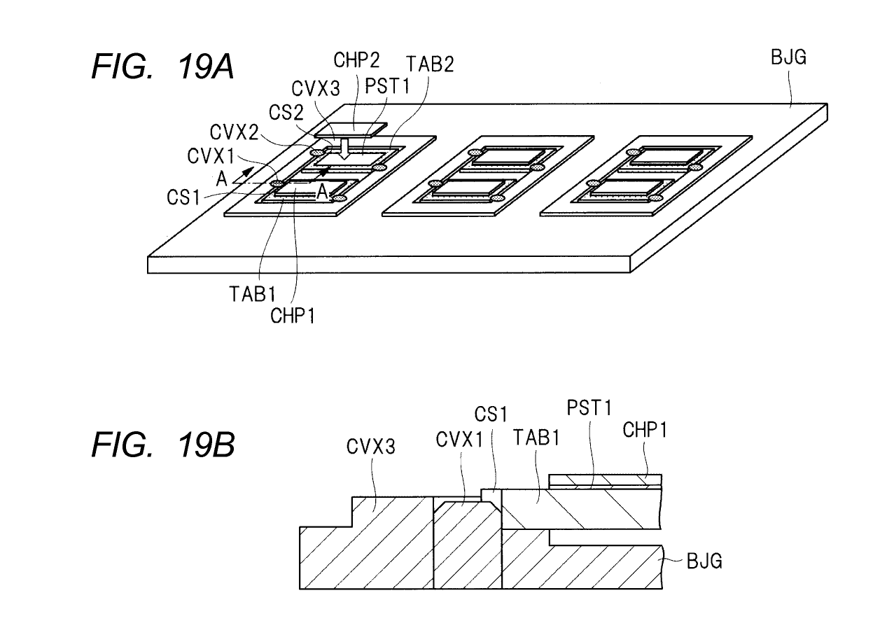

3. Chip Mounting Step Then, as shown in FIG. 19, the semiconductor chip CHP1 with the IGBT formed therein is mounted over the chip mounting portion TAB1, and the semiconductor chip CHP2 with the diode formed therein is mounted over the chip mounting portion TAB2.

Specifically, the semiconductor chip CHP1 has a first front surface including the IGBT and provided with the emitter electrode pad EP, as well as a first back surface provided with the collector electrode and being opposite to the first surface. Such a semiconductor chip CHP1 is mounted over the chip mounting portion TAB1, so that the chip mounting portion TAB1 is electrically coupled to the first back surface of the semiconductor chip CHP1. Likewise, the semiconductor chip CHP2 has a second front surface including the diode and provided with the anode electrode pad ADP, as well as a second back surface provided with the cathode electrode and being opposite to the second surface. Such a semiconductor chip CHP2 is mounted over the chip mounting portion TAB2, so that the chip mounting portion TAB2 is electrically coupled to the second back surface of the semiconductor chip CHP2.

Thus, in the semiconductor chip CHP2 with the diode formed therein, the cathode electrode pad formed at the back surface of the semiconductor chip CHP2 is arranged in contact with the chip mounting portion TAB2 via the conductive paste PST1. As a result, the anode electrode pad ADP formed at the front surface of the semiconductor chip CHP2 are faced upward (see FIG. 12).

On the other hand, in the semiconductor chip CHP1 with the IGBT formed therein, the collector electrode pad formed at the back surface of the semiconductor chip CHP1 is arranged in contact with the chip mounting portion TAB1 via the conductive paste PST1.

The emitter electrode pad EP and electrode pads which are formed at the front surface of the semiconductor chip CHP1 are faced upward (see FIG. 12). The electrode pads include the gate electrode pad GP, the temperature sensing electrode pad TCP, the temperature sensing electrode pad TAP, the current sensing electrode pad SEP, and the kelvin sensing electrode pad KP.

Note that regarding the order of mounting the semiconductor chip CHP1 with the IGBT formed therein, and the semiconductor chip CHP2 with the diode formed therein, the semiconductor chip CHP1 may be mounted first, and then the semiconductor chip CHP2 may be mounted. Alternatively, the semiconductor chip CHP2 may be mounted first, and then the semiconductor chip CHP1 may be mounted.

Thereafter, the heating treatment is applied to the chip mounting portion TAB1 with the semiconductor chip CHP1 mounted thereover, and the chip mounting portion TAB2 with the semiconductor chip CHP2 mounted thereover.

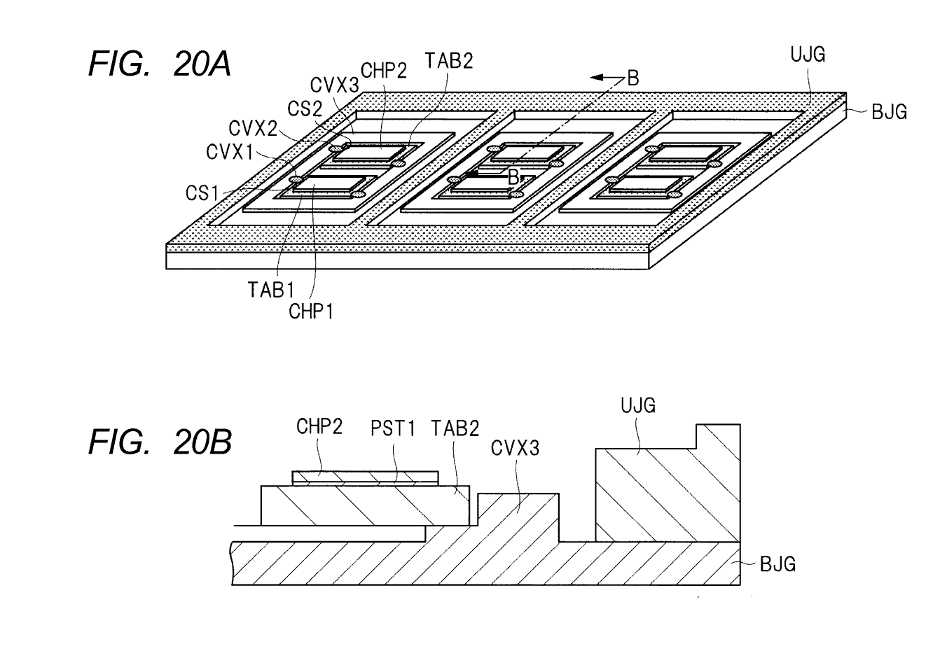

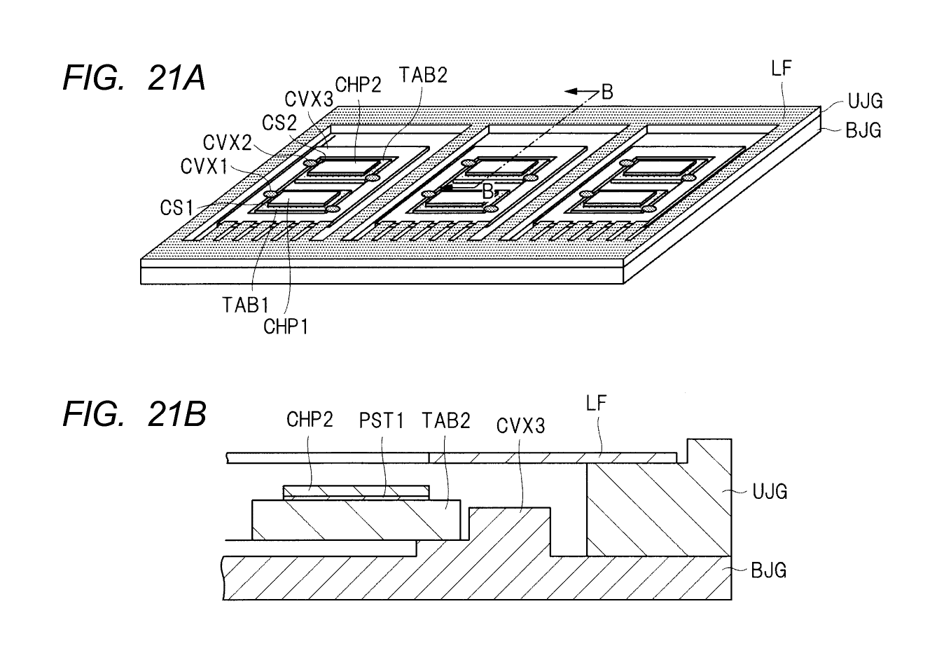

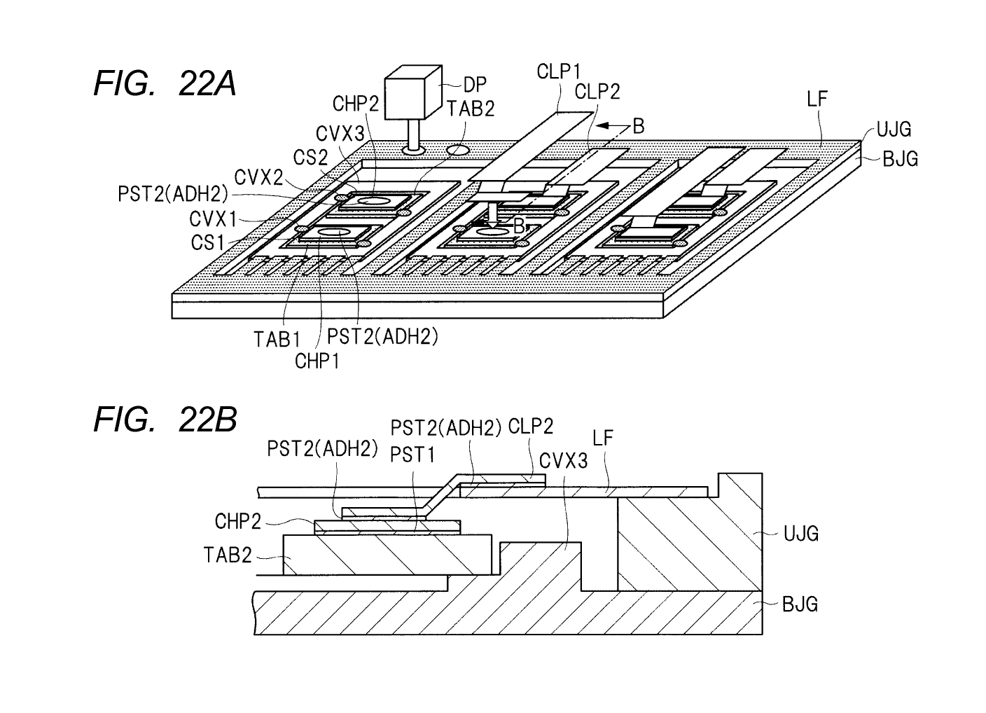

4. Upper Jig Arrangement Step Subsequently, as shown in FIGS. 20A and 20B, the upper jig UJG is arranged over the main surface of the lower jig BJG. At this time, as shown in FIG. 20B, the upper surface of the upper jig UJG is higher than the front surface of the semiconductor chip CHP2 mounted over the chip mounting portion TAB2. Similarly, although not shown, the upper surface of the upper jig UJG is higher than the surface of the semiconductor chip CHP1 mounted over the chip mounting portion TAB1. As can be seen from FIG. 20B, regarding the height with the main surface of the lower jig BJG set as a reference, the following relationship is satisfied: main surface of the lower jig BJG<height of convex portion CVX3<upper surface of chip mounting portion TAB2 (chip mounting portion TAB1)<front surface of semiconductor chip CHP2 (semiconductor chip CHP1)<upper surface of upper jig UJG.
5. Substrate (Lead Frame) Provision Step Next, as shown in FIGS. 21A and 21B, a lead frame LF with leads is provided, and the lead frame LF is positioned over the upper jig UJG. At this time, in the first embodiment, the upper jig UJG intervenes between the lower jig BJG and the lead frame LF, whereby the height of arrangement of the lead frame LF is higher than that of the surface of the semiconductor chip CHP1 (semiconductor chip CHP2). That is, as shown in FIG. 20B, in terms of the height with main surface of the lower jig BJG set as a reference, the following relationship is satisfied: main surface of the lower jig BJG<height of convex portion CVX3<upper surface of chip mounting portion TAB2 (chip mounting portion TAB1)<front surface of semiconductor chip CHP2 (semiconductor chip CHP1)<upper surface of upper jig UJG. Thus, the height of the lead frame LF arranged over the upper jig UJG is higher than that of the surface of the semiconductor chip CHP1 (semiconductor chip CHP2). In this way, the upper jig UJG serves as a spacer that makes the height of arrangement of the lead frame LF higher than that of the front surface of the semiconductor chip CHP1 (semiconductor chip CHP2).
6. Electrical Coupling Step Subsequently, as shown in FIGS. 22A and 22B, a conductive paste PST2 (conductive adhesive ADH2) is supplied over the anode electrode pad ADP of the semiconductor chip CHP2, as well as over the emitter electrode pad EP of the semiconductor chip CHP1, for example, by using a dispenser DP. Further, the conductive paste PST2 is also supplied over a part of the region with the leads (see FIG. 12).

Suitable materials for the conductive paste PST2 for use can include, for example, a silver paste, and a solder (solder paste) having a high melting point. The conductive paste PST2 may contain the same component as the above-mentioned conductive paste PST1, and may contain a different component from the conductive paste PST1.

Then, the lead (lead LD1A of FIG. 12) is electrically coupled to the semiconductor chip CHP1, and the lead (lead LD1B of FIG. 12) is electrically coupled to the semiconductor chip CHP2. Specifically, first, as shown in FIG. 22A, the clip CLP2 are mounted on the anode electrode pad ADP of the semiconductor chip CHP2 and the lead (lead LD1B of FIG. 12), thereby electrically coupling the anode electrode pad ADP to the lead (lead LD1B of FIG. 12) (see FIG. 12). Thereafter, as shown in FIG. 22A, the clip CLP1 are mounted on the emitter electrode pad EP of the semiconductor chip CHP1 and the lead (lead LD1A of FIG. 12), thereby electrically coupling the emitter electrode pad EP to the lead (lead LD1A of FIG. 12) (see FIG. 12). At this time, as shown in FIG. 22A, the clip CLP1 is mounted to cross a part of the clip CLP2. Through this step, the lead frame LF, the chip mounting portion TAB1, and the chip mounting portion TAB2 are integrated together. Thereafter, a heat treatment is applied to the lead frame LF, chip mounting portion TAB1, and chip mounting portion TAB2 integrated.

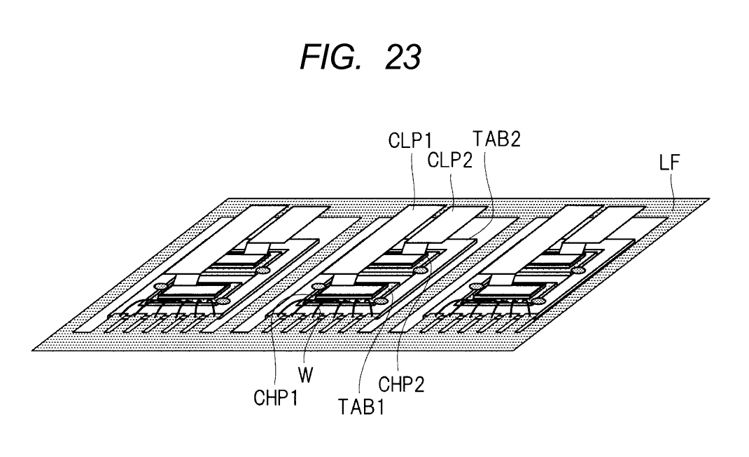

Then as shown in FIG. 23, after removing the upper jig UJG and the lower jig BJG, a wire bonding step is performed. For example, as illustrated in FIGS. 11 and 12, the lead LD2 is electrically coupled to the gate electrode pad GP by the wire W, and the lead LD2 is electrically coupled to the temperature sensing electrode pad TCP by the wire W. Further, as illustrated in FIGS. 11 and 12, the lead LD2 is electrically coupled to the temperature sensing electrode pad TAP by the wire W, and the lead LD2 is electrically coupled to the temperature sensing electrode pad SEP by the wire W. Moreover, as show in FIG. 12, the lead LD2 is electrically coupled to the kelvin sensing electrode pad KP by the wire W. Here, in the first embodiment, as shown in FIG. 12, the lead LD2 is arranged opposite to the lead LD1A coupled to the clip CLP1 and to the lead LD1B coupled to the clip CLP2, whereby the wire bonding process can be performed without consideration of interruption between the wire W and the clips CLP1 and CLP2.

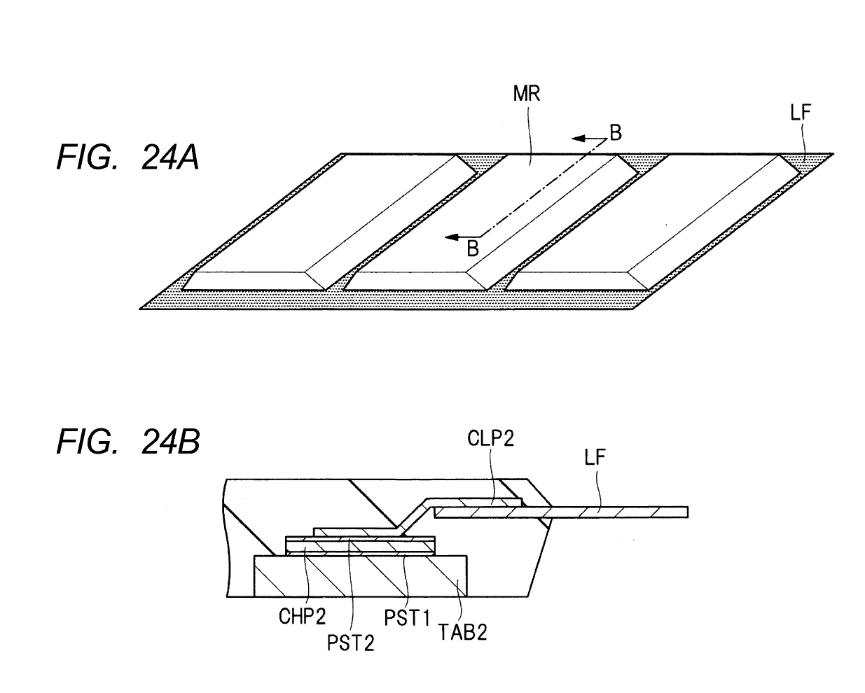

7. Sealing (Molding) Step Then, as shown in FIGS. 24A and 24B, the sealing body MR is formed to seal the semiconductor chip CHP1, the semiconductor chip CHP2, a part of the chip mounting portion TAB1, a part of the chip mounting portion TAB2, a part of the lead LD1A, a part of the lead LD1B, respective parts of the leads LD2, the clips CLP1 and CLP2, and the wires W.

At this time, as shown in FIG. 12, in the sealing body MR, the lead LD1A and the lead LD1B protrude from the side S1 of the sealing body MR, and the leads LD2 protrude from the side S2 of the sealing body MR. Further, as shown in FIGS. 12B and 12C, the lower surface of the chip mounting portion TAB1 and the lower surface of the chip mounting portion TAB2 are exposed from the lower surface of the sealing body MR. In the first embodiment, the chip mounting portions TAB1 and TAB2 have the stepped structures formed at their side surfaces. Thus, in the first embodiment, the stepped portion serves as the stopper, which can prevent the chip mounting portions TAB1 and TAB2 from falling off the sealing body MR.

8. Exterior Plating Step Thereafter, a tie-bar (not shown) included in the lead frame LF is cut. Then, a plated layer (tin film) which is a conductive film is formed over the chip mounting portion TAB1, chip mounting portion TAB2, the surface of a part of the lead LD1A, the surface of a part of the lead LD1B, and the surfaces of parts of the leads LD2, which are exposed from the lower surface of the sealing body MR (see FIG. 12).
9. Marking Step Information (marks), such as a product name and a product No., is formed on the surface of the resin molding body MR. Note that methods for forming a mark can include a printing method by use of a printing system, a method for impressing a mark by irradiating the surface of a molding body with laser light.
10. Singulation Step Subsequently, a part of the lead LD1A, a part of the lead LD1B, and respective parts of the leads LD2 are cut to separate the lead LD1A, lead LD1B, and leads LD2 from the lead frame LF (see FIG. 12). In this way, for example, the semiconductor device PAC1 in the first embodiment shown in FIG. 12 can be manufactured. Thereafter, the lead LD1A, the lead LD1B, and the second leads LD2 are respectively molded. After a testing process, e.g., of electric characteristics of the semiconductor devices, only the semiconductor devices PAC1 that are judged to be of good quality will be shipped. In the way described above, the semiconductor device PAC1 of the first embodiment can be manufactured.

### <Alignment Among Lower Jig, Upper Jig, and Lead Frame>

Since the manufacturing method of the semiconductor device in the first embodiment described above use the lower jig BJG and the upper jig UJG, the alignment among the lower jig BJG, upper jig UJG, and lead frame LF is needed. In the first embodiment 1, the alignment among the lower jig BJG, upper jig UJG, and lead frame LF is devised. The points devised focusing on the alignment among the lower jig BJG, upper jig UJG, and lead frame LF will be described below with reference to the accompanying drawings.

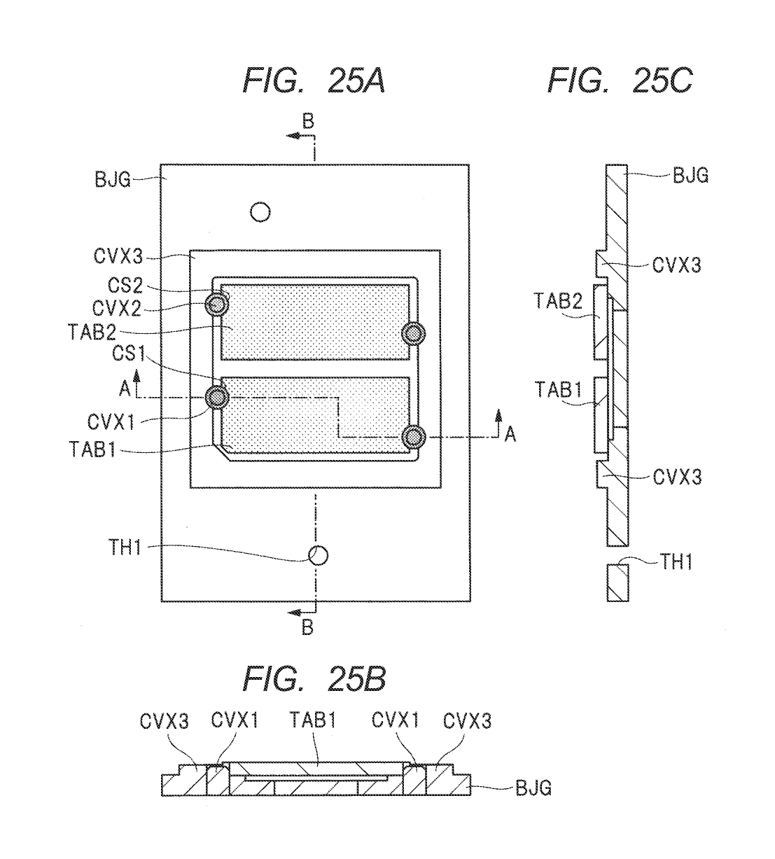

FIG. 25A is a plan view showing a state in which the chip mounting portions TAB1 and TAB2 are arranged over the lower jig BJG in the first embodiment. FIG. 25B is a cross-sectional view taken along the line A-A of FIG. 25A, and FIG. 25C is a cross-sectional view taken along the line B-B of FIG. 25A. As shown in FIGS. 25A and 25C, the lower jig BJG of the first embodiment is provided with a through hole TH1 (concave portion). The through hole TH1 is provided, for example, by setting the position of one convex portion CVX1 as a reference as shown in FIG. 25A.

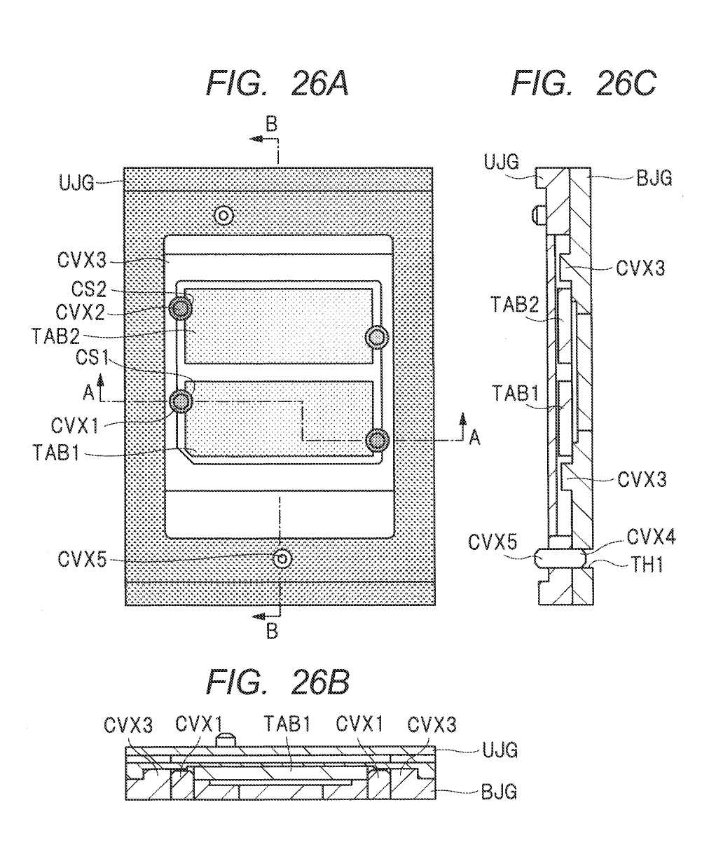

Subsequently, FIG. 26A is a plan view showing a state in which the upper jig UJG is arranged over the lower jig BJG in the first embodiment. FIG. 26B is a cross-sectional view taken along the line A-A of FIG. 26A, and FIG. 26C is a cross-sectional view taken along the line B-B of FIG. 26A. As shown in FIGS. 26A and 26C, the upper jig UJG of the first embodiment is provided with a convex portion CVX4 protruding downward, and a convex portion CVX5 protruding upward. These convex portions CVX4 and CVX5 are provided, for example, by setting the position of one convex portion CVX1 as a reference as shown in FIG. 26A. Accordingly, the through hole TH1 formed in the lower jig BJG and the convex portion CVX4 formed in the upper jig UJG are located in the same position with the same object (convex portion CVX1) set as the reference. As shown in FIG. 26C, the convex portion CVX4 formed in the upper jig UJG can be inserted into the through hole TH1 formed in the lower jig BJG. As a result, the convex portion CVX4 is inserted into the through hole TH1, thereby performing alignment between the lower jig BJG and the upper jig UJG.

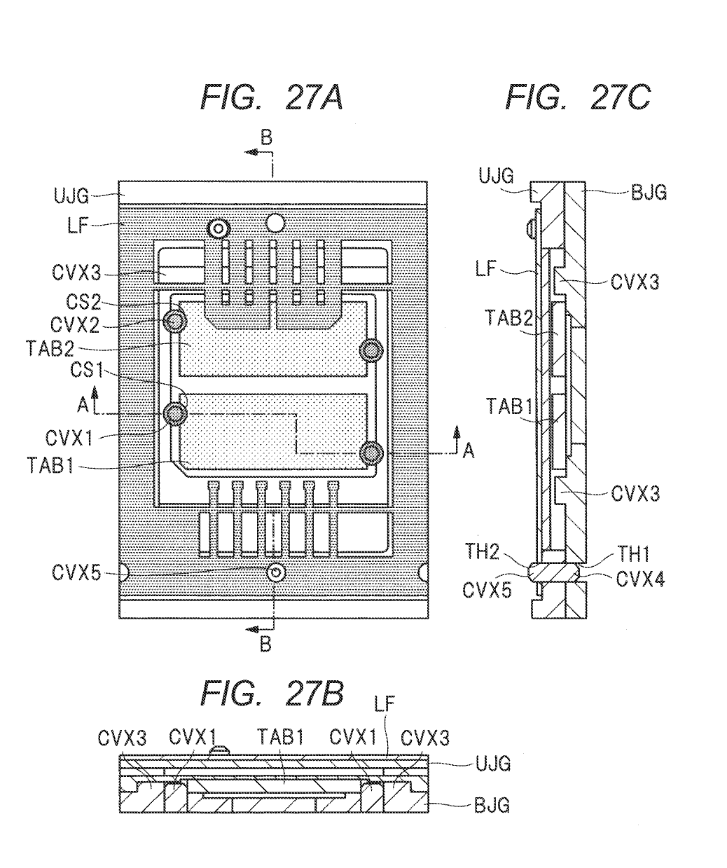

Subsequently, FIG. 27A is a plan view showing a state in which the lead frame LF is arranged over the upper jig UJG in the first embodiment. FIG. 27B is a cross-sectional view taken along the line A-A of FIG. 27A, and FIG. 27C is a cross-sectional view taken along the line B-B of FIG. 27A. As shown in FIGS. 27A and 27C, the lead frame LF of the first embodiment is provided with a through hole TH2. The through hole TH2 is provided, for example, by setting the position of one convex portion CVX1 shown in FIG. 27A as a reference. Accordingly, the convex portion CVX5 formed in the upper jig UJG and the through hole TH2 formed in the lead frame LF are located in the same position with the same object (convex portion CVX1) set as the reference. As shown in FIG. 27C, the convex portion CVX5 formed in the upper jig UJG can be inserted into the through hole TH2 formed in the lead frame LF. As a result, the convex portion CVX5 is inserted into the through hole TH2, thereby performing alignment between the upper jig UJG and the lead frame LF.

As mentioned above, the manufacturing method of the semiconductor device in the first embodiment involves inserting the convex portion CVX4 into the through hole TH1, and inserting the convex portion CVX5 into the through hole TH2, thereby achieving alignment among the lower jig BJG, the upper jig UJG, and the lead frame LF.

### Features of First Embodiment

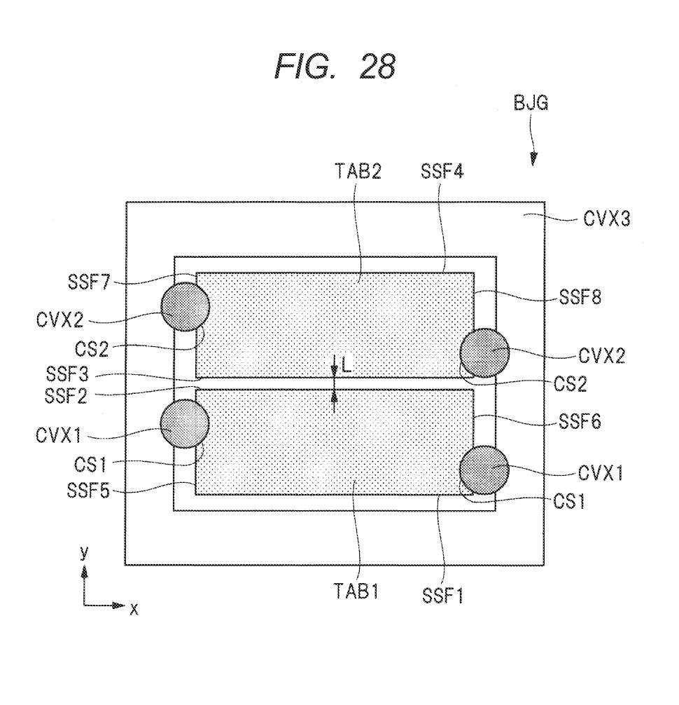

Subsequently, the features of the first embodiment will be described with reference to the accompanying drawings. FIG. 28 is a schematic diagram showing a state of the chip mounting portions TAB1 and TAB2 that are fixed by the lower jig BJG. As shown in FIG. 28, the lower jig BJG is provided with the convex portions CVX1 and the convex portions CVX2. By the convex portions CVX1, the chip mounting portion TAB1 is fixed. Similarly, by the convex portions CVX2, the chip mounting portion TAB2 is fixed.

As shown in FIG. 28, the chip mounting portion TAB1 has a side surface SSF1, a side surface SSF2 opposed to the side surface SSF1, and side surfaces SSF5 and SSF6 that are opposed to each other, and which intersect the side surfaces SSF1 and SSF2.

On the other hand, as shown in FIG. 28, the chip mounting portion TAB2 has a side surface SSF3, a side surface SSF4 opposed to the side surface SSF3, and side surfaces SSF7 and SSF8 that intersect the side surfaces SSF3 and SSF4 and which are opposed to each other.

At this time, the chip mounting portion TAB1 and the chip mounting portion TAB2 are arranged such that the side surface SSF2 of the chip mounting portion TAB1 faces the side surface SSF3 of the chip mounting portion TAB2. Here, a first aspect of the first embodiment in the invention is that the convex portions CVX1 are pressed against the side surfaces SSF5 and SSF6 that are opposed to each other, thereby fixing the chip mounting portion TAB1. In detail, the cutout portion CS1 is formed in each of the side surface SSF5 and side surface SSF6 of the chip mounting portion TAB1. By fitting the convex portions CVX1 into the respective cutout portions CS1, the chip mounting portion TAB1 is fixed by the convex portions CVX1. In other words, the first aspect of the first embodiment in the invention is that the convex portions CVX1 are pressed against the side surfaces SSF5 and SSF6 other than the side surface SSF2 of the chip mounting portion TAB1, thereby fixing the chip mounting portion TAB1 without forming a convex portion CVX1 corresponding to the side surface SSF2 of the chip mounting portion TAB1. That is, the first aspect of the first embodiment in the invention is that the convex portion CVX2 is provided not in the position corresponding to the side surface SSF3 of the chip mounting portion TAB2, but at a side surface of the chip mounting portion TAB1 other than the side SSF3, thereby fixing the chip mounting portion TAB2.

Likewise, the first aspect of the first embodiment in the invention is that the convex portions CVX2 are pressed against the side surfaces SSF7 and SSF8 that are opposed to each other, thereby fixing the chip mounting portion TAB2. In detail, the cutout portion CS2 is formed in each of the side surface SSF7 and side surface SSF8 of the chip mounting portion TAB2. By fitting the convex portions CVX2 into the respective cutout portions CS2, the chip mounting portion TAB2 is fixed by the convex portions CVX2. In other words, the first aspect of the first embodiment is that the convex portions CVX2 are pressed against the side surfaces SSF7 and SSF8 other than the side surface SSF3 of the chip mounting portion TAB2, thereby fixing the chip mounting portion TAB2 without forming a convex portion CVX1 corresponding to the side surface SSF2 of the chip mounting portion TAB1. That is, the first aspect of the first embodiment in the invention is that the convex portion CVX1 is provided not in the position corresponding to the side surface SSF2 of the chip mounting portion TAB1, but at a side surface of the chip mounting portion TAB1 other than the side SSF2, thereby fixing the chip mounting portion TAB1.

Thus, the chip mounting portion TAB1 is fixed by the convex portions CVX1 formed in the lower jig BJG, and the chip mounting portion TAB2 is fixed by the convex portions CVX2 formed in the lower jig BJG, so that the chip mounting portions TAB1 and TAB2 can be fixed, while reducing a distance between the side surface SSF2 of the chip mounting portion TAB1 and the side surface SSF3 of the chip mounting portion TAB2 which face each other. This is because, as shown in FIG. 28, the convex portions CVX1 and CVX2 need not to be provided between the side surface SSF2 of the chip mounting portion TAB1 and the side surface SSF3 of the chip mounting portion TAB2 which face each other so as to position the chip mounting portions TAB1 and TAB2. That is, in the first embodiment, the chip mounting portions TAB1 and TAB2 can be positioned precisely without providing the convex portions CVX1 and CVX2 between the side surface SSF2 of the chip mounting portion TAB1 and the side surface SSF3 of the chip mounting portion TAB2 which face each other. This means it is not necessary to ensure a space for positioning the convex portions CVX1 and CVX2 between the side surface SSF2 of the chip mounting portion TAB1 and the side surface SSF3 of the chip mounting portion TAB2 which face each other. Thus, as shown in FIG. 28, a distance L between the side surface SSF2 of the chip mounting portion TAB1 and the side surface SSF3 of the chip mounting portion TAB2 which face each other can be decreased. As a result, the first embodiment can reduce the size of the semiconductor device, while improving the positioning accuracy of the chip mounting portions TAB1 and TAB2.

That is, in the first embodiment, first, the chip mounting portion TAB1 is fixed by the convex portions CVX1 formed in the lower jig BJG, and the chip mounting portion TAB2 is fixed by the convex portions CVX2 formed in the lower jig BJG. Thus, the positioning accuracy of the chip mounting portions TAB1 and TAB2 can be improved. This means that a misalignment between the chip mounting portions TAB1 and TAB2 is less likely to occur. The misalignment can be minimized, thereby suppressing the contact between the chip mounting portions TAB1 and TAB2 which would otherwise cause the misalignment, even if the distance between the chip mounting portions TAB1 and TAB2 is set narrow (first advantage).

The first embodiment does not need to form the convex portion CVX1 corresponding to the side surface SSF2 of the chip mounting portion TAB1, as well as the convex portion CVX2 corresponding to the side surface SSF3 of the chip mounting portion TAB2, which eliminates the necessity of ensuring a space for arranging the convex portions CVX1 and CVX2 between the side surface SSF2 of the chip mounting portion TAB1 and the side surface SSF3 of the chip mounting portion TAB2 which face each other. Thus, the distance between the chip mounting portions TAB1 and TAB2 can be decreased as much as possible (second advantage).

Thus, in the first aspect of the first embodiment, both the above-mentioned first and second advantages can be obtained. The synergy between the first and second advantages can more effectively achieve the downsizing of the semiconductor device, while improving the positioning accuracy of the chip mounting portions TAB1 and TAB2.

For example, in terms of higher performance and downsizing of the power module, a packaged semiconductor device (packaged product) is used as a component of the power module designed for the inverter circuit dedicated to the SR motor. In this case, the packaged product needs two chip mounting portions that are electrically isolated from each other in view of the characteristics of the inverter circuit dedicated to the SR motor.

For this reason, particularly, to downsize the packaged product dedicated to the SR motor, these two chip mounting portions TAB1 and TAB2 need to be as close to each other as possible while remaining electrically isolated mutually. This leads to the need for a technique that can accurately position and arrange two chip mounting portions TAB1 and TAB2 close to each other in a manufacturing procedure of the packaged product dedicated to the SR motor.

In this aspect, when the semiconductor device in the first embodiment is applied to the above-mentioned packaged product dedicated to the SR motor, the first embodiment can use the lower jig BJG having the features described above to position the chip mounting portions TAB1 and TAB2 as close to each other as possible while improving the positioning accuracy of these chip mounting portions TAB1 and TAB2. As a result, the use of the lower jig BJG with the features of the first embodiment can achieve the downsizing of the semiconductor device, especially, the semiconductor device dedicated to the SR motor, while improving the positioning accuracy of the chip mounting portions TAB1 and TAB2.

Next, the advantages of technical idea in the first embodiment will be described in comparison with the first and second related arts.

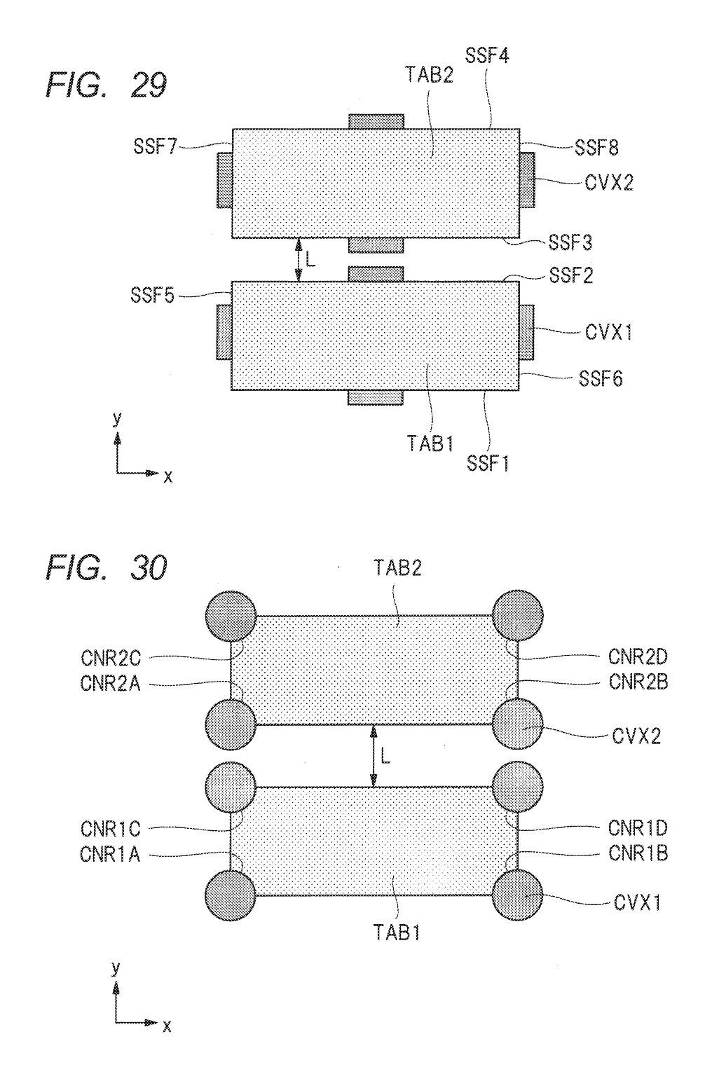

For example, FIG. 29 is a diagram for explaining the first related art. Referring to FIG. 29, the chip mounting portion TAB1 has convex portions CVX1 corresponding to four side surfaces of the chip mounting portion TAB1 (side surface SSF1, side surface SSF2, side surface SSF5, and side surface SSF6). Likewise, the chip mounting portion TAB2 has convex portions CVX2 corresponding to four side surfaces of the chip mounting portion TAB2 (side surface SSF3, side surface SSF4, side surface SSF7, and side surface SSF8).

Thus, even in the first related art, the chip mounting portion TAB1 is fixed by the convex portions CVX1, and the chip mounting portion TAB2 is fixed by the convex portions CVX2, which can improve the positioning accuracy of the chip mounting portions TAB1 and TAB2.

However, in the first related art, unlike the first embodiment, as shown in FIG. 29, the convex portions CVX1 and CVX2 are provided between the side surface SSF2 of the chip mounting portion TAB1 and the side surface SSF3 of the chip mounting portion TAB2 which face each other.

As a result, the first related art needs to ensure a space for arranging the convex portions CVX1 and CVX2 between the side surface SSF2 of the chip mounting portion TAB1 and the side surface SSF3 of the chip mounting portion TAB2 which face each other, thereby increasing a distance L shown in FIG. 29. This means that the first related art makes it difficult to narrow the distance L between the chip mounting portion TAB1 and the chip mounting portion TAB2. Thus, there is a room for improvement of the first related art in terms of downsizing the semiconductor device with the two chip mounting portions separated from each other.

Subsequently, FIG. 30 is a diagram for explaining the second related art. Referring to FIG. 30, the chip mounting portion TAB1 is provided with convex portions CVX1 corresponding to four respective corners (corners CNR1A to CNR1D) of the rectangular chip mounting portion TAB1. Likewise, the chip mounting portion TAB2 is provided with convex portions CVX2 corresponding to four respective corners (corners CNR2A to CNR2D) of the rectangular chip mounting portion TAB2.

Thus, even in the second related art, the chip mounting portion TAB1 is fixed by the convex portions CVX1, and the chip mounting portion TAB2 is fixed by the convex portions CVX2, which can improve the positioning accuracy of the chip mounting portions TAB1 and TAB2.

However, unlike the first embodiment, as shown in FIG. 30, the second related art needs to avoid the interference between the convex portion CVX1 formed at the corner CNR1C of the chip mounting portion TAB1, and the convex portion CVX2 formed at the corner CNR2A of the chip mounting portion TAB2. Likewise, the second related art also needs to avoid the interference between the convex portion CVX1 formed at the corner CNR1D of the chip mounting portion TAB1, and the convex portion CVX2 formed at the corner CNR2B of the chip mounting portion TAB2.

As a result, the second related art needs to ensure a space between the chip mounting portions TAB1 and TAB2 so as to avoid the interference between the convex portions CVX1 and CVX2, resulting in a large distance L shown in FIG. 30. This also means that the second related art also makes it difficult to narrow the distance L between the chip mounting portion TAB1 and the chip mounting portion TAB2. Thus, there is a room for improvement of the second related art in terms of downsizing the semiconductor device with the two chip mounting portions separated from each other.

In contrast, in the first embodiment, as show in FIG. 28, the chip mounting portion TAB1 is fixed by the convex portions CVX1 formed in the lower jig BJG, and the chip mounting portion TAB2 is fixed by the convex portions CVX2 formed in the lower jig BJG. This can improve the positioning accuracy of the chip mounting portions TAB1 and TAB2. Referring to FIG. 28, in the first embodiment, the convex portion CVX1 is not provided corresponding to the side surface SSF2 of the chip mounting portion TAB1, and the convex portion CVX2 is not provided corresponding to the side surface SSF3 of the chip mounting portion TAB2. Thus, the first embodiment does not need to ensure a space for positioning the convex portions CVX1 and CVX2 between the side surface SSF2 of the chip mounting portion TAB1 and the side surface SSF3 of the chip mounting portion TAB2 which face each other, thereby decreasing the distance L between the chip mounting portions TAB1 and TAB2. Therefore, the first embodiment can have the excellent effects of downsizing the semiconductor device, while improving the positioning accuracy of the chip mounting portions TAB1 and TAB2. That is, the technical idea of the first embodiment in the invention can solve the disadvantages associated with the first and second related art described above. As a result, the technical idea of the first embodiment has the advantages over the first and second related arts described above.

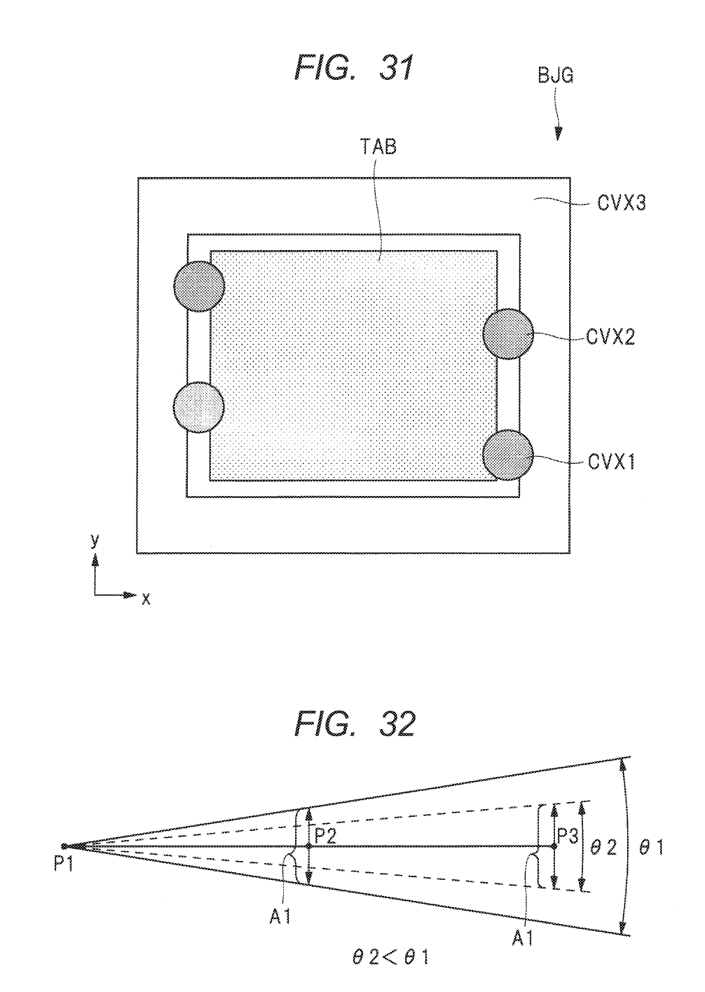

Subsequently, the third advantage obtained by the first aspect of the first embodiment will be described below. Referring to FIG. 28, in the first embodiment, the convex portion CVX1 is not provided corresponding to the side surface SSF2 of the chip mounting portion TAB1, and the convex portion CVX2 is not provided corresponding to the side surface SSF3 of the chip mounting portion TAB2. Thus, for example, as shown in FIG. 31, the lower jig BJG used in the first embodiment can also be used as a positioning jig for fixing one large chip mounting portion TAB.

Basically, that is, the lower jig BJG of the first embodiment is basically supposed to be used in a manufacturing procedure for a semiconductor device dedicated to the SR motor that includes two chip mounting portions electrically isolated from each other as shown in FIG. 28. The use of the lower jig BJG in the first embodiment in such applications can effectively downsize the semiconductor device, while improving the positioning accuracy of the chip mounting portion TAB1 and the chip mounting portion TAB2.

Note that the lower jig BJG in the first embodiment can be applied not only the manufacturing procedure for the semiconductor device dedicated to the SR motor as described above, but also, for example, a manufacturing procedure for a semiconductor device for a PM motor having one chip mounting portion. This is because in the first aspect of the first embodiment, as shown in FIG. 28, the convex portion CVX1 is not provided corresponding to the side surface SSF2 of the chip mounting portion TAB1, and the convex portion CVX2 is not provided corresponding to the side surface SSF3 of the chip mounting portion TAB2, so that one large chip mounting portion TAB can be positioned at the lower jig BJG as shown in FIG. 31.

In this way, the lower jig BJG of the first embodiment can be used not only for a manufacturing procedure for a semiconductor device having two chip mounting portions separated from each other, but also for a manufacturing procedure for a semiconductor device having only one chip mounting portion. It is to be understood that the lower jig BJG of this embodiment is a positioning jig with excellent general versatility. That is, the first aspect of the first embodiment in the invention also has a third advantage that it can provide the positioning jig with excellent general versatility.

Subsequently, a second aspect of the first embodiment in the invention will be described. Referring to FIG. 28, the second aspect of the first embodiment in the invention is that a distance of a straight line between the cutout portion CS1 formed at the side surface SSF5 of the chip mounting portion TAB1 and the cutout portion CS1 formed at the side surface SSF6 of the chip mounting portion TAB1 is set longer than the length of one long side of the upper surface of the chip mounting portion TAB1. That is, the second aspect of the first embodiment is that a y-coordinate of the cutout portion CS1 formed at the side surface SSF5 differs from a y-coordinate of the cutout portion CS1 formed at the side surface SSF6. In other words, it can also be understood that a straight line connecting the cutout portion CS1 formed at the side surface SSF5 and the cutout portion CS1 formed at the side surface SSF6 is not in parallel with one long side of the chip mounting portion TAB1, or forms an angle of more than 0 degree with respect to the one long side of the chip mounting portion TAB1. Further, in other words, it can be considered that in the second aspect of the first embodiment, the positional relationship between the cutout portion CS1 formed at the side surface SSF5 and the cutout portion CS1 formed at the side surface SSF6 is an asymmetric relationship with respect to the central line extending in the y direction while allowing a straight line between these cutout portions CS1 to pass through the center of the one long side of the chip mounting portion TAB1. From a different point of view, the second aspect of the first embodiment can describe that a y-coordinate of the convex portion CVX1 fitted into the cutout portion CS1 formed at the side surface SSF5 differs from a y-coordinate of the convex portion CVX1 fitted into the cutout portion CS1 formed at the side surface SSF6. Here, although the above description has focused on the chip mounting portion TAB1, obviously, the same relationship is satisfied even in focusing on the chip mounting portion TAB2.

The second aspect of the first embodiment described in this way can have the following advantages, which will be described below.

FIG. 32 is a diagram for explaining a first advantage obtained by the second aspect of the first embodiment. Referring to FIG. 32, for example, a distance between points P1 and P2 corresponds to a length of one long side of the chip mounting portion TAB1 shown in FIG. 28. The distance between the points P1 and P3 is a distance between the convex portion CVX1 fitted into the cutout portion CS1 formed at the side surface SSF5 and the convex portion CVX1 fitted into the cutout portion CS1 formed at the side surface SSF6 as shown in FIG. 28. The distance between the points P1 and P3 corresponds to a distance achieved by the second aspect of the first embodiment. For convenience, the distance between the points P1 and P2 is called a first distance, and the distance between the points P1 and P3 is called a second distance.

Referring to FIG. 32, at this time, for example, if the distance between the convex portion CVX1 corresponding to the side surface SSF5 and the convex portion CVX1 corresponding to the side surface SSF6 is assumed to be the first distance, a displacement amount of the chip mounting portion TAB1 in the θ direction (rotational direction) becomes θ1 when a misalignment A1 occurs between the convex portion CVX1 corresponding to the side surface SSF5 and the convex portion CVX1 corresponding to the side surface SSF6.

On the other hand, as shown in FIG. 32, for example, the distance between the convex portion CVX1 corresponding to the side surface SSF5 and the convex portion CVX1 corresponding to the side surface SSF6 is assumed to be a second distance. In this case, if a misalignment amount A1 occurs between the convex portion CVX1 corresponding to the side surface SSF5 and the convex portion CVX1 corresponding to the side surface SSF6, a displacement amount of the chip mounting portion TAB1 in the direction at an angle θ (rotational direction) becomes θ2

That is, as the distance between the convex portion CVX1 corresponding to the side surface SSF5 and the convex portion CVX1 corresponding to the side surface SSF6 becomes longer, the displacement amount in the θ direction (rotational direction) of the chip mounting portion TAB1 for the same misalignment amount A1 is decreased. This means that as the distance between the convex portion CVX1 corresponding to the side surface SSF5 and the convex portion CVX1 corresponding to the side surface SSF6 becomes longer, the displacement amount in the θ direction (rotational direction) of the chip mounting portion TAB1 for the misalignment amount of the convex portion CVX1 can become smaller. That is, as the distance between the convex portion CVX1 at the side surface SSF5 and the convex portion CVX1 at the side surface SSF6 becomes longer, the positioning accuracy of the chip mounting portion TAB1 is improved. For example, as shown in FIG. 28, the first embodiment employs the second aspect that the respective convex portions CVX1 are arranged such that the y-coordinate of the convex portion CVX1 corresponding to the side surface SSF5 differs from the y-coordinate of the convex portion CVX1 corresponding to the side surface SSF6. Accordingly, the first embodiment can have the first advantage of improving the positioning accuracy of the chip mounting portion TAB1, as a result of increasing the distance between the convex portion CVX1 at the side surface SSF5 and the convex portion CVX1 at the side surface SSF6.

Subsequently, the second advantage obtained by the second aspect of the first embodiment will be described below. As shown in FIG. 28, in the second aspect of the first embodiment, the positional relationship between the cutout portion CS1 at the side surface SSF5 and the cutout portion CS1 at the side surface SSF6 is an asymmetric relationship with respect to the central line extending in the y direction while allowing a straight line between these cutout portions CS1 to pass through the center of the one long side of the chip mounting portion TAB1. When the front and back surfaces of the chip mounting portion TAB1 are turned upside down, for example, due to an operation error, the chip mounting portion TAB1 cannot be fitted into the convex portion CVX1. Accordingly, the second aspect of the first embodiment can have the second advantage of preventing the operation error in advance.

### First Modified Example

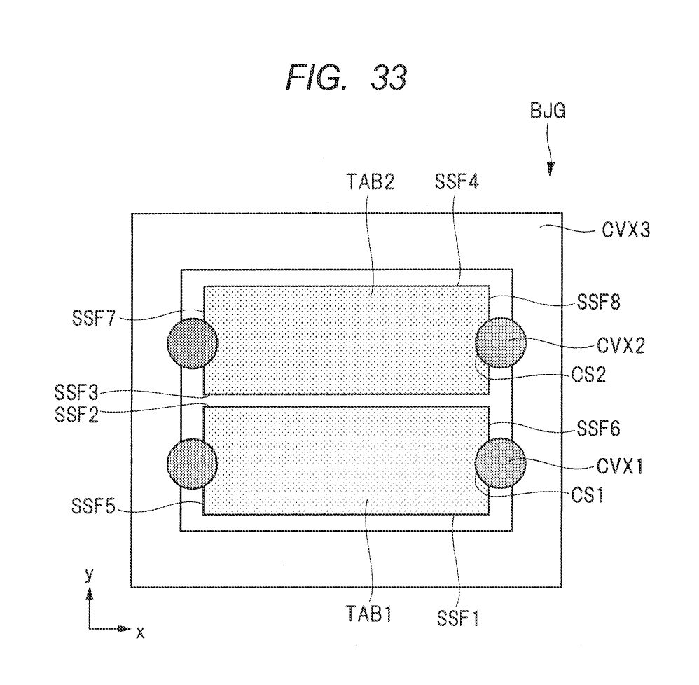

Next, a first modified example of the first embodiment will be described. FIG. 33 is a schematic diagram showing a state in which the chip mounting portions TAB1 and TAB2 are fixed by the lower jig BJG in the first modified example. For example, focusing on the chip mounting portion TAB1, as show in FIG. 33, the convex portion CVX1 corresponding to the side surface SSF5 of the chip mounting portion TAB1 and the convex portion CVX1 corresponding to the side surface SSF6 of the chip mounting portion TAB1 may be arranged such that a virtual line connecting these convex portions is in parallel with one long side of the upper surface of the rectangular chip mounting portion TAB1. In other words, the respective convex portions CVX1 can be arranged in such a manner that a y-coordinate of the convex portion CVX1 corresponding to the side surface SSF5 is identical to that of the convex portion CVX1 corresponding to the side surface SSF6.

Likewise, focusing on the chip mounting portion TAB2, the convex portion CVX2 corresponding to the side surface SSF7 of the chip mounting portion TAB2 and the convex portion CVX2 corresponding to the side surface SSF8 of the chip mounting portion TAB2 may be arranged such that a straight line connecting these convex portions is in parallel with one long side of the upper surface of the rectangular chip mounting portion TAB2. In other words, the respective convex portions CVX2 can be arranged in such a manner that a y-coordinate of the convex portion CVX2 corresponding to the side surface SSF7 is identical to that of the convex portion CVX2 corresponding to the side surface SSF8.

### Second Modified Example

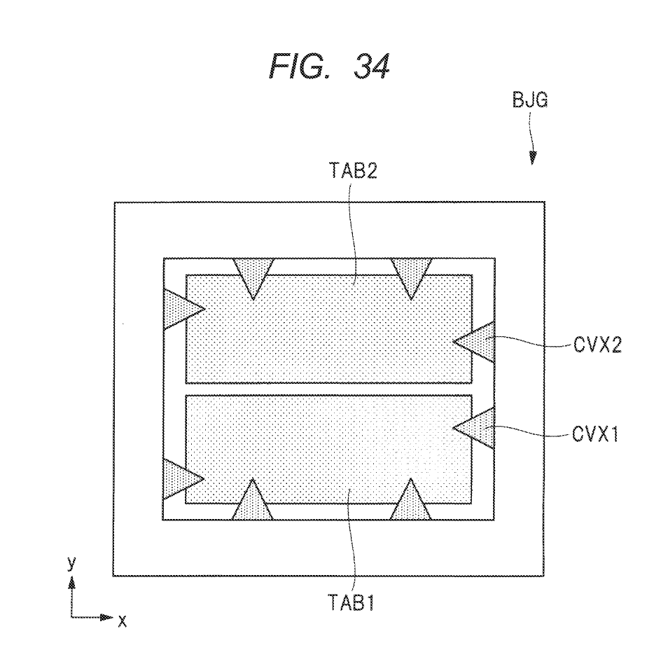

Subsequently, a second modified example of the first embodiment will be described. FIG. 34 is a schematic diagram showing a state in which the chip mounting portions TAB1 and TAB2 are fixed by the lower jig BJG in the second modified example. As shown in FIG. 34, the convex portion CVX1 and the convex portion CVX2 may have a triangle planar shape, in addition to a circular shape like the first embodiment.

### Third Modified Example

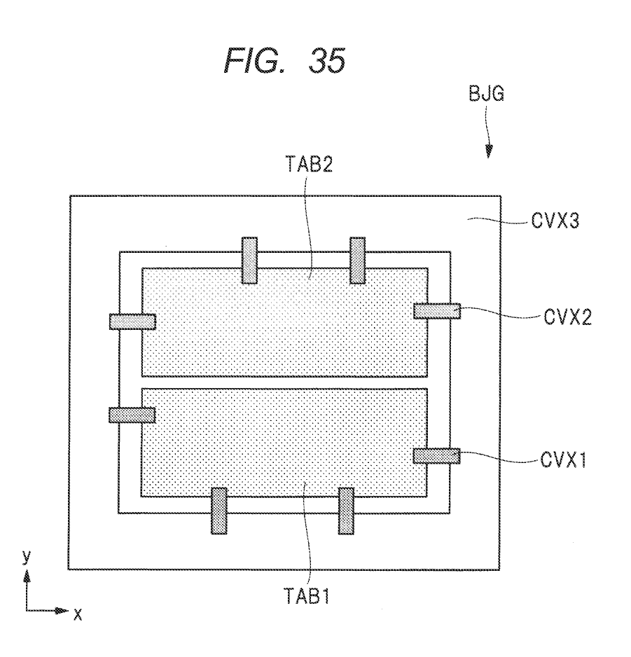

Next, a third modified example of the first embodiment will be described. FIG. 35 is a schematic diagram showing a state in which the chip mounting portions TAB1 and TAB2 are fixed by the lower jig BJG in the third modified example. As shown in FIG. 35, the convex portion CVX1 and the convex portion CVX2 may have an oblong planar shape, such as a rectangular planar shape, or a square planar shape, in addition to a circular planar shape like the first embodiment.

### Fourth Modified Example

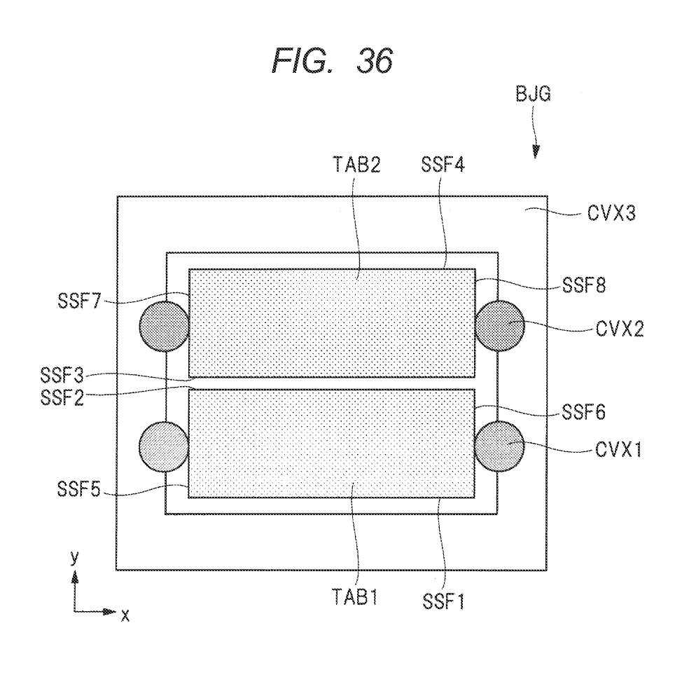

Next, a fourth modified example of the first embodiment will be described below. FIG. 36 is a schematic diagram showing a state in which the chip mounting portions TAB1 and TAB2 are fixed by the lower jig BJG in the fourth modified example. As shown in FIG. 36, for example, focusing on the chip mounting portion TAB1, the convex portions CVX1 may be pressed against the side surface SSF5 without forming any cutout portion at the side surface SSF5 of the chip mounting portion TAB1, and the convex portions CVX1 may be pressed against the side surface SSF6 without forming any cutout portion at the side surface SSF6 of the chip mounting portion TAB1.

Likewise, as shown in FIG. 36, for example, also in the chip mounting portion TAB2, the convex portions CVX2 may be pressed against the side surface SSF7 without forming any cutout portion at the side surface SSF7 of the chip mounting portion TAB2, and the convex portions CVX1 may be pressed against the side surface SSF8 without forming any cutout portion at the side surface SSF8 of the chip mounting portion TAB1.

In this case, since no cutout portion is provided in each of the chip mounting portions TAB1 and TAB2, the planar size of each of the chip mounting portions TAB1 and TAB2 can be decreased. For example, the semiconductor chip with the IGBT formed therein is mounted over the chip mounting portion TAB1, and the semiconductor chip with the diode formed therein is mounted over the chip mounting portion TAB2. Thus, when the chip mounting portions TAB1 and TAB2 have the respective cutout portions, the cutout portions and the semiconductor chip need to be arranged not to overlap each other, whereby the planar size of each of the chip mounting portions TAB1 and TAB2 increases by areas forming the cutout portions.

On the other hand, like the fourth modified example, when no cutout portion is provided in each of the chip mounting portions TAB1 and TAB2, it is unnecessary to ensure regions for forming cutout portions in the respective chip mounting portions TAB1 and TAB2. Thus, the fourth modified example can further decrease the planar size of each of the chip mounting portions TAB1 and TAB2.

### Fifth Modified Example

Although the first embodiment has described the example in which the chip mounting portions TAB1 and TAB2 have the same planar shape, the technical idea of the first embodiment is not limited thereto, and may be applied to a structure in which the lateral width (width in the x direction) of the chip mounting portion TAB1 differs from that of the chip mounting portion TAB2, as well as a structure in which the longitudinal width (width in the y direction) of the chip mounting portion TAB1 differs that of the chip mounting portion TAB2.

### Second Embodiment

In a second embodiment, a description will be given of a technical idea that provides a common convex portion in the lower jig BJG, the common convex portion being in contact with both the chip mounting portions TAB1 and TAB2 separated from each other.

### Features of Second Embodiment

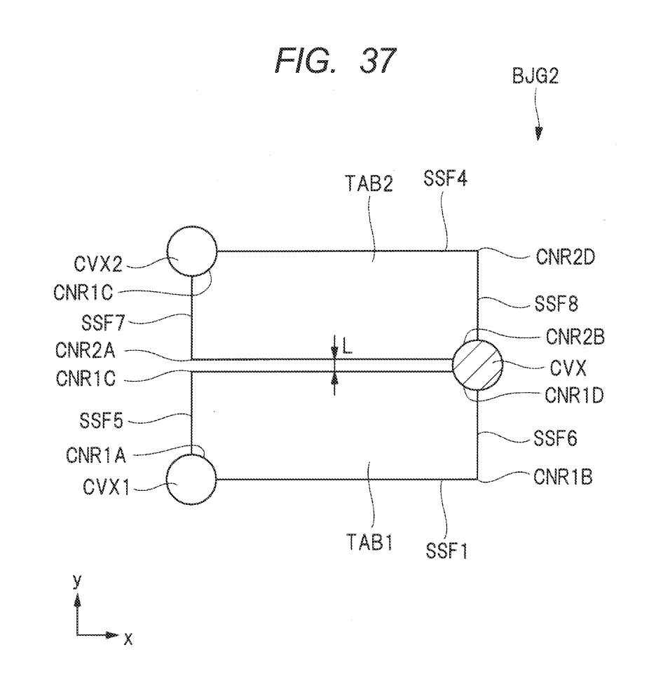

FIG. 37 is a schematic diagram showing a state in which the chip mounting portions TAB1 and TAB2 are fixed by the lower jig BJG in a second embodiment. As shown in FIG. 37, the chip mounting portion TAB1 has a rectangular shape with its corners CNR1A to CNR1D. Similarly, the chip mounting portion TAB2 has a rectangular shape with its corners CNR2A to CNR2D.

Here, as illustrated in FIG. 37, the lower jig BJG has a convex portion CVX1, a convex portion CVX2, and a common convex portion CVX. The chip mounting portion TAB1 has cutout portions formed at the respective corners CNR1A and CNR1D. The convex portion CVX1 is fitted into the cutout portion formed at the corner CNR1A, and the common convex portion CVX is fitted into the cutout portion formed at the corner CNR1D. On the other hand, the chip mounting portion TAB2 has cutout portions formed at the respective corners CNR2B and CNR2C. The common convex portion CVX is fitted into the cutout portion formed at the corner CNR2B, and the convex portion CVX2 is fitted into the cutout portion formed at the corner CNR2C.

Referring to FIG. 37, the feature of the second embodiment in the invention is that the common convex portion CVX in contact with both the chip mounting portions TAB1 and TAB2 separated from each other is provided in the lower jig BJG. Specifically, the common convex portion CVX is fitted into both the cutout portion formed at the corner CNR1D of the chip mounting portion TAB1 and the cutout portion formed at the corner CNR2B of the chip mounting portion TAB2.

That is, in the second embodiment, the common convex portion CVX is pressed against the corner CNR1D on the end side of the side surface SSF2 of the chip mounting portion TAB1, and the convex portion CVX1 is pressed against the corner CNR1A positioned on a diagonal line with respect to the corner CNR1D of the chip mounting portion TAB1, thereby positioning the chip mounting portion TAB1 over the main surface of the lower jig BJG. Further, in the second embodiment, the common convex portion CVX is pressed against the corner CNR2B located on the end side of the side surface SSF3 of the chip mounting portion TAB2, and facing the corner CNR1D, and the convex portion CVX2 is pressed against the corner CNR2C positioned on a diagonal line with respect to the corner CNR2B of the chip mounting portion TAB2, thereby positioning the chip mounting portion TAB2 over the main surface of the lower jig BJG.

In this way, in the second embodiment, the common convex portion CVX in contact with both the chip mounting portions TAB1 and TAB2 is used in the chip mounting portions TAB1 and TAB2 separated from each other, without respectively forming different convex portions in contact with the side surface SSF2 of the chip mounting portion TAB1 and the side surface SSF3 of the chip mounting portion TAB2, which face each other. Thus, the second embodiment can decrease the distance L between the side surface SSF2 of the chip mounting portion TAB1 and the side surface SSF3 of the chip mounting portion TAB2 which face each other. That is, the second embodiment of the invention has the technical idea that the common convex portion is shared between the side surface SSF2 of the chip mounting portion TAB1 and the side surface SSF3 of the chip mounting portion TAB2, which can downsize the semiconductor device, while improving the positioning accuracy of the chip mounting portions TAB1 and TAB2.

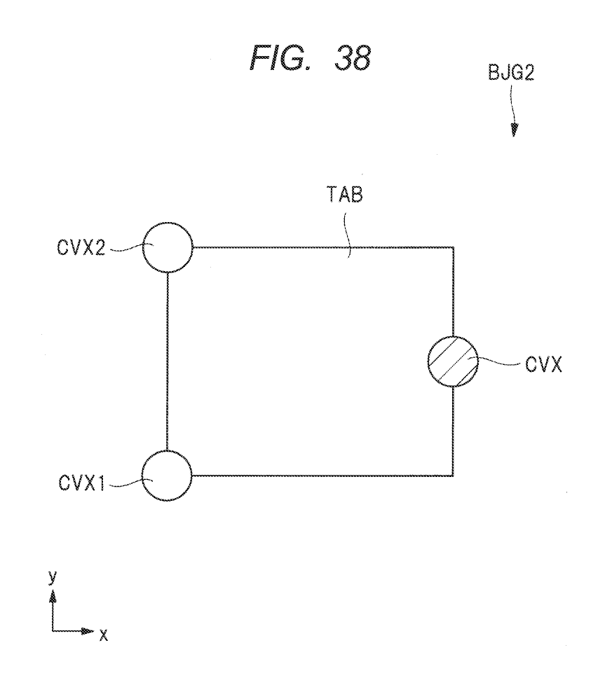

Note that, for example, as shown in FIG. 38, the lower jig BJG used in the second embodiment can also be used as a positioning jig for fixing one large chip mounting portion TAB.

That is, the lower jig BJG of the second embodiment is basically supposed to be used in a manufacturing procedure for a semiconductor device dedicated to the SR motor that includes two chip mounting portions electrically isolated from each other, like FIG. 37. The use of the lower jig BJG of the second embodiment in such applications can effectively downsize the semiconductor device, while improving the positioning accuracy of the chip mounting portion TAB1 and the chip mounting portion TAB2.

Note that the lower jig BJG in the second embodiment can be applied not only to the manufacturing procedure for the semiconductor device dedicated to the SR motor as described above, but also to a manufacturing procedure for a semiconductor device for a PM motor having one chip mounting portion.

Accordingly, the lower jig BJG of the second embodiment can be used not only for a manufacturing procedure for a semiconductor device having two separated chip mounting portions, but also for a manufacturing procedure for a semiconductor device having only one chip mounting portion. It is to be understood that the lower jig BJG of the second embodiment is a positioning jig with excellent general versatility. That is, the second embodiment in the invention has an advantage that it can provide the positioning jig with excellent general versatility.

### <Definition of Corner>

Finally, the definition of the term “corner” as used in the second embodiment will be described below. The term “corner” as used in the present specification is an intersection of one side surface of the chip mounting portion and another side surface intersecting the one side surface in the planar view. The “corner” will be specifically described below.

For example, as shown in FIG. 37, the chip mounting portion TAB1 has its corners CNR1A to CNR1D. Focusing on the corner CNR1A, for example, the term “corner CNR1A” as used herein is defined as an intersection of the side surfaces SSF1 and SSF5 in the planar view. Likewise, the term “corner CNR1D” as used herein is defined as an intersection of the side surfaces SSF2 and SSF6 in the planar view. The phrase “convex portion corresponding to the corner” as used in the present specification means a convex portion having the “corner” on a boundary line or therein in the planar view. For example, referring to FIG. 37, the phrase “convex portion corresponding to the corner CNR1A” is considered as the convex CVX1 including the intersection of the side surfaces SSF1 and SSF5. Similarly, the phrase “convex portion corresponding to the corners CNR1D and CNR2B” as used herein is considered as the common convex portion CVX including the intersection of the side surfaces SSF2 and SSF6, and the intersection of the side surfaces SSF3 and SSF8.

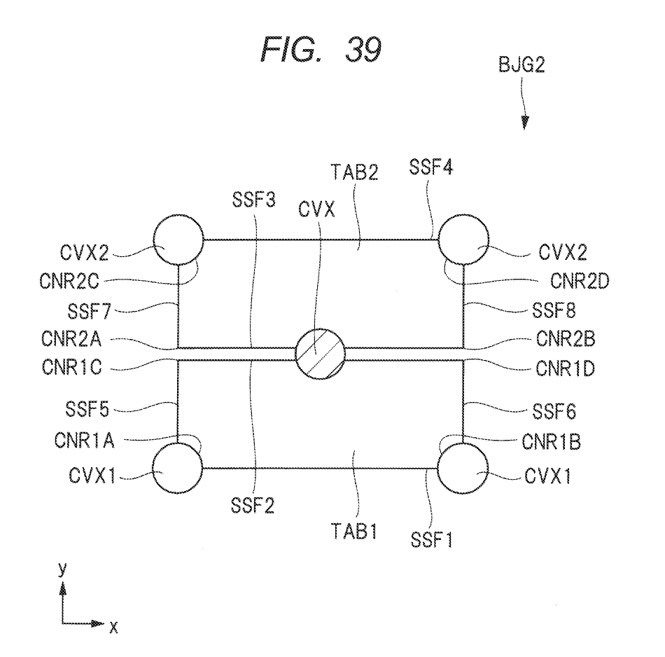

The reason why the present specification defines the “convex portion corresponding to the corner” in this way is to clarify that, for example, the common convex portion CVX shown in FIG. 39 is excluded from the “convex portion corresponding to the corner”. That is, the common convex portion CVX shown in FIG. 39 does not include any “corner (intersection)” at all, and thus is excluded from the term “convex portion corresponding to the corner” defined in the present specification.

Here, the reason why the common convex portion CVX shown in FIG. 39 is excluded from the technical idea of the second embodiment is that the common convex portion CVX shown in FIG. 39 can decrease a distance between the side surface SSF2 of the chip mounting portion TAB1 and the side surface SSF3 of the chip mounting portion TAB2, but becomes as an obstacle to mounting of the semiconductor chip over the chip mounting portions TAB1 and TAB2. That is, in the common convex portion CVX shown in FIG. 39, cutout portions are formed in the vicinity of the center of the chip mounting portion TAB1, and in the vicinity of the center of the chip mounting portion TAB2. As a result, the common convex portion CVX shown in FIG. 39 generates a dead space in which the semiconductor chip cannot be mounted over the chip mounting portions TAB1 and TAB2, leading to an increase of the planar size of each of the chip mounting portions TAB1 and TAB2, making it difficult to downsize the semiconductor device.

Although the invention made by the inventors have been specifically described based on the embodiments, it is obvious that the invention is not limited to the embodiments, and that various modifications and changes can be made to those embodiments without departing from the scope of the invention.

The above-mentioned embodiments include the following embodiments.

(Supplemental 1)

A method for manufacturing a semiconductor device includes the steps of: (a) arranging a first chip mounting portion and a second chip mounting portion over a first main surface of a first jig, the first jig having a plurality of convex portions formed at the first main surface; (b) mounting a first semiconductor chip over the first chip mounting portion, and mounting a second semiconductor chip over the second chip mounting portion; (c) after the step (b), arranging a lead frame with a plurality of leads, over the first main surface of the first jig; (d) electrically coupling a first electrode pad of the first semiconductor chip to a first lead of the lead frame via a first conductive member, and electrically coupling a second electrode pad of the second semiconductor chip to a second lead of the lead frame via a second conductive member; and (e) forming a sealing body by sealing the first semiconductor chip, the second semiconductor chip, a part of the first chip mounting portion, a part of the second chip mounting portion, a part of the first lead, and a part of the second lead with resin, in which the first chip mounting portion has a first upper surface over which the first semiconductor chip is mounted, a first lower surface opposite to the first upper surface, a first side surface positioned between the first upper surface and the first lower surface in a thickness direction thereof, and a second side surface opposite to the first side surface, in which the second chip mounting portion has a second upper surface over which the second semiconductor chip is mounted, a second lower surface opposite to the second upper surface, a third side surface positioned between the second upper surface and the second lower surface in a thickness direction thereof, and a fourth side surface opposite to the third side surface, in which the convex portions include a first convex portion, a second convex portion, and a common convex portion, in which the step (a) includes the sub-steps of: (a1) arranging the first chip mounting portion and the second chip mounting portion over the first main surface of the first jig such that the second side surface of the first chip mounting portion faces the third side surface of the second chip mounting portion; and (a2) positioning the first chip mounting portion over the first main surface of the first jig by pressing a first corner on one end side of the second side surface of the first chip mounting portion, against the common convex portion, while pressing a second corner positioned on a diagonal line with respect to the first corner of the first chip mounting portion, against the first convex portion, and positioning the second chip mounting portion at the first main surface of the first jig by pressing a third corner located on one end side of the third side surface of the second chip mounting portion and opposed to the first corner, against the common convex portion, while pressing a fourth corner positioned on a diagonal line with respect to the third corner of the second chip mounting portion, against the second convex portion.

(Supplemental 2)

In the method for manufacturing a semiconductor device described in the supplemental 1, the first corner is provided with a first cutout portion corresponding to the common convex portion; the third corner is provided with a second cutout portion corresponding to the common convex portion; in the step (a2), the first chip mounting portion is positioned over the first main surface of the first jig by pressing the first cutout portion against the common convex portion, and the second chip mounting portion is positioned over the first main surface of the first jig by pressing the second cutout portion against the common convex portion.

What is claimed is:

1. A method for manufacturing a semiconductor device, comprising the steps of:
(a) arranging a first chip mounting portion and a second chip mounting portion over a first main surface of a first jig, the first jig having a plurality of convex portions formed at the first main surface;
(b) mounting a first semiconductor chip over the first chip mounting portion, and mounting a second semiconductor chip over the second chip mounting portion;
(c) after the step (b), arranging a lead frame with a plurality of leads, over the first main surface of the first jig;
(d) electrically coupling a first electrode pad of the first semiconductor chip to a first lead of the lead frame via a first conductive member, and electrically coupling a second electrode pad of the second semiconductor chip to a second lead of the lead frame via a second conductive member; and
(e) forming a sealing body by sealing the first semiconductor chip, the second semiconductor chip, a part of the first chip mounting portion, a part of the second chip mounting portion, a part of the first lead, and a part of the second lead with resin,
wherein the first chip mounting portion has a first upper surface over which the first semiconductor chip is mounted, a first lower surface opposite to the first upper surface, a first side surface positioned between the first upper surface and the first lower surface in a thickness direction thereof, and a second side surface opposed to the first side surface,
wherein the second chip mounting portion has a second upper surface over which the second semiconductor chip is mounted, a second lower surface opposite to the second upper surface, a third side surface positioned between the second upper surface and the second lower surface in a thickness direction thereof, and a fourth side surface opposed to the third side surface,
wherein the step (a) comprises the sub-steps of:
(a1) arranging the first chip mounting portion and the second chip mounting portion over the first main surface of the first jig such that the second side surface of the first chip mounting portion faces the third side surface of the second chip mounting portion; and
(a2) positioning the first chip mounting portion over the first main surface of the first jig by respectively pressing a plurality of first convex portions of the first jig against a plurality of side surfaces of the first chip mounting portion other than the second side surface, and positioning the second chip mounting portion over the first main surface of the first jig by respectively pressing a plurality of second convex portions of the first jig against a plurality of side surfaces of the second chip mounting portion other than the third side surface.

2. The method for manufacturing a semiconductor device according to claim 1,
wherein each of the first chip mounting portion and the second chip mounting portion has a quadrilateral planar shape,
wherein the first chip mounting portion has a fifth side surface and a sixth side surface that intersect the first side surface and the second side surface, the fifth side surface and the sixth side surface being opposed to each other,
wherein the second chip mounting portion has a seventh side surface and an eighth side surface that intersect the third side surface and the fourth side surface, the seventh side surface and the eighth side surface being opposed to each other, and
wherein in the step (a2), the first convex portions are in contact with only the fifth side surface and the sixth side surface, and the second convex portions are in contact with only the seventh side surface and the eight side surface.

3. The method for manufacturing a semiconductor device according to claim 2,
wherein the fifth side surface and the sixth side surface of the first chip mounting portion are provided with first cutout portions corresponding to the respective first convex portions, and
wherein the seventh side surface and the eighth side surface of the second chip mounting portion are provided with second cutout portions corresponding to the respective second convex portions.

4. The method for manufacturing a semiconductor device according to claim 3,
wherein the first cutout portion reaches the first upper surface and the first lower surface of the first chip mounting portion, and
wherein the second cutout portion reaches the second upper surface and the second lower surface of the second chip mounting portion.

5. The method for manufacturing a semiconductor device according to claim 3,
wherein the first cutout portion reaches only the first lower surface of the first chip mounting portion without reaching the first upper surface of the first chip mounting portion, and
wherein the second cutout portion reaches only the second lower surface of the second chip mounting portion without reaching the second upper surface of the second chip mounting portion.

6. The method for manufacturing a semiconductor device according to claim 5,
wherein an area of the first upper surface of the first chip mounting portion is larger than that of the first lower surface exposed from the sealing body, and
wherein an area of the second upper surface of the second chip mounting portion is larger than that of the second lower surface exposed from the sealing body.

7. The method for manufacturing a semiconductor device according to claim 1,
wherein a planar shape of the first upper surface of the first chip mounting portion is rectangular, and a planar shape of the second upper surface of the second chip mounting portion is rectangular, and
wherein the first side surface of the first chip mounting portion is a side surface including a first long side of the first upper surface, the second side surface of the first chip mounting portion is a side surface including a second long side of the first upper surface, the third side surface of the second chip mounting portion is a side surface including a third long side of the second upper surface, and the fourth side surface of the second chip mounting portion is a side surface including a fourth long side of the second upper surface.

8. The method for manufacturing a semiconductor device according to claim 7,
wherein each of a fifth side surface including a first short side of the first upper surface and a sixth side surface including a second short side of the first upper surface is provided with at least one first cutout portion corresponding to one first convex portion among the first convex portions, and
wherein each of a seventh side surface including a third short side of the second upper surface and an eighth side surface including a fourth short side of the second upper surface is provided with at least one second cutout portion corresponding to one second convex portion among the second convex portions.

9. The method for manufacturing a semiconductor device according to claim 8,
wherein a distance of a straight line between the first cutout portion formed at the fifth side surface and the first cutout portion formed at the sixth side surface is longer than a length of the first long side of the first upper surface, and
wherein a distance of a straight line between the second cutout portion formed at the seventh side surface and the second cutout portion formed at the eighth side surface is longer than a length of the third long side of the second upper surface.

10. The method for manufacturing a semiconductor device according to claim 1,
wherein the step (b) comprises the sub-steps of:
(b1) arranging a printing mask over the first main surface of the first jig so as to be positioned above the first upper surface of the first chip mounting portion and the second upper surface of the second chip mounting portion;
(b2) squeegeeing a conductive adhesive at a surface of the printing mask by a squeegee, and supplying the conductive adhesive from an opening formed in the printing mask to over the first upper surface of the first chip mounting portion and the second upper surface of the second chip mounting portion; and
(b3) mounting the first semiconductor chip over the first upper surface of the first chip mounting portion via the conductive adhesive, and mounting the second semiconductor chip over the second upper surface of the second chip mounting portion via the conductive adhesive,
wherein a third convex portion is formed around the first convex portions and the second convex portions over the first main surface of the first jig,
wherein with the first main surface defined as a reference surface, a height of the third convex portion is higher than that of each of the first convex portions and the second convex portions, and lower than each of a height of the first upper surface of the first chip mounting portion and a height of the second upper surface of the second chip mounting portion,
wherein in the step (b1), the printing mask is arranged over the first main surface of the first jig such that a back surface of the printing mask is in contact with the first upper surface of the first chip mounting portion and the second upper surface of the second chip mounting portion, with a gap from the third convex portion maintained,
wherein in the step (b2), a height of the third convex portion is set such that the squeegee passes through over the third convex portion, and that once the printing mask is bent, the back surface of the printing mask is in contact with the third convex portion.

11. The method for manufacturing a semiconductor device according to claim 10,
wherein the conductive adhesive is a solder paste.

12. The method for manufacturing a semiconductor device according to claim 1,
wherein the step (c) comprises the sub-steps of:
(c1) arranging a second jig with a second main surface thereof facing the first main surface of the first jig; and
(c2) arranging the lead frame over a third main surface opposite to the second main surface of the second jig,
wherein a fourth convex portion is formed over the second main surface of the second jig, and a fifth convex portion is formed over the third main surface of the second jig,
wherein a concave portion into which the fourth convex portion is insertable is formed at the first main surface of the first jig,
wherein a through hole into which the fifth convex portion is insertable is formed in the lead frame,
wherein the concave portion, the fourth convex portion, and the fifth convex portion are provided with one of the first convex portions set as a reference,
wherein the step (c1) includes inserting the fourth convex portion of the second jig into the concave portion of the first jig, and
wherein the step (c2) includes inserting the fifth convex portion of the second jig into the through hole of the lead frame.
